(19) United States
(12) Patent Application Publication
(10) Pub. No.: US 2010/0295713 A1
(43) Pub. Date: Nov. 25, 2010

(54) CODING APPARATUS, DECODING APPARATUS, CODE TRANSFORMING APPARATUS, AND PROGRAM

(75) Inventors: Ikuro Ueno, Tokyo (JP); Ryuta Suzuki, Tokyo (JP); Tomohiro Kimura, Tokyo (JP)

Correspondence Address: BIRCH STEWART KOLASCH & BIRCH, PO BOX 747, FALLS CHURCH, VA, 22040-0747, US

(73) Assignee: Mitsubishi Electric Corporation, Tokyo (JP)

(21) Appl. No.: 12/596,650

(22) PCT Filed: Jan. 7, 2008
(86) PCT No.: PCT/JP2008/050028

§ 371 Date: Nov. 25, 2009

(30) Foreign Application Priority Data
Apr. 18, 2007 (JP) 2007-109629

(51) Int. Cl. H03M 7/30

(52) U.S. Cl. 341/87

(57) ABSTRACT

An coding apparatus includes a number-of-additional-bits calculating means 107 for calculating the number of bits which can be set, as additional bits, at an end of a code sequence in which an information source is entropy-coded on the basis of information about the end of the code sequence, the information being driven from code data which form the code sequence, and an additional bit coding means 108 for setting the additional bits having the number of bits at the end of the code sequence.

### FIELD OF THE INVENTION

The present invention relates to a coding apparatus, a decoding apparatus and a code transforming apparatus each of which embeds additional bits in an entropy-coded sequence, and a program which causes a computer to operate as these apparatuses.

### BACKGROUND OF THE INVENTION

Arithmetic coding is widely used as a method capable of implementing efficient coding according to the probability of occurrence of an information source symbol. As an image coding system, a QM coder which is a binary arithmetic coding system is adopted for JPEG (Joint Photographic Experts Group) and JBIG (Joint Bi-level Image experts Group) which are normal standard image compression methods, and an MQ coder which is a binary arithmetic coding system is adopted for JPEG2000 and JBIG2.

In these binary arithmetic coding systems, binary decimal coordinates on a number line which is equal or larger than 0.0 and is smaller than 1.0 are defined as a code. In ₜhis process, the above-mentioned range on the number line is defined as a valid interval width A, and is divided into an MPS (More Probable Symbol) and an LPS (Less Probable Symbol) in proportion to the probability of occurrence of a binary symbol, and a partial interval corresponding to a symbol which has actually occurred is defined as a new valid interval and the dividing is then repeated. In this case, the MPS is a more probable symbol showing that a data value having a higher probability of occurrence has occurred, and the LPS is a less probable symbol showing that a data value having a lower probability of occurrence has occurred.

Coordinates having a degree of accuracy which is needed to show the valid interval updated with a final symbol are outputted as a code. During the process, the lower bound of the valid interval is calculated and is updated as well as the valid interval width which is the difference between the upper bound and the lower bound of the valid interval. Coordinates, in which successive 1 s at the end thereof are discarded, having a minimum number of effective digits within the valid interval can be selected as a final code.

In the arithmetic coding, subtraction-type arithmetic coding is widely used in order to reduce the throughput of the code calculating operation. In the subtraction-type arithmetic coding, an approximate value of a partial interval LSZ assigned to an LPS is selected from a table which is prepared in advance on the basis of the probability of occurrence of a symbol. At this time, a normalizing process of, when the valid interval width becomes smaller than ½, multiplying the valid interval width by a power of 2 to enlarge the valid interval width in such a way that the valid interval width becomes ½ or more is carried out. Accordingly, the number of decimal places at the time of the calculation is maintained constant.

Because the details of the coding process and the decoding process carried out by of the MQ coder are described in nonpatent reference 1, the details of the coding process and the decoding process will be omitted hereafter. Hereafter, a process of processing the end of a coding register which is carried out at the end of the coding (referred to as flush from here on) will be explained. As mentioned above, in the arithmetic coding, a binary decimal having a degree of accuracy which is needed in order to show the valid interval width A determined by the finally-coded symbol is transmitted as a code. It is not necessary to transmit, as this code, all the bits including up to the least significant bit of the coding register in the MQ coder.

For the MQ coder, there is provided a rule of, when there is no longer any code to be decoded at the time of decoding of an inputted code sequence, supplementing this code sequence with, as a code, a value of 0xFF (0x shows a hexadecimal number). It is known that it is guaranteed by this rule that the decoding is correctly carried out if a byte including the 15th bit counted from the highermost bit of the result of the arithmetic operation using the finally-coded symbol which is stored in the coding register of FIG. 3 is outputted as a code.

The flush process described in nonpatent reference 1 will be explained. When the valid interval width at the time after the arithmetic operation using the finally-coded symbol is expressed as A and the coding register value is expressed as C, the following calculations are carried out first: an intermediate value TEMPC=C+A and C=C OR 0xFFFF (OR indicates a bitwise logical OR). Next, whether or not the coding register value C is equal to or larger than TEMPC is determined. At this time, when the value C of the coding register is smaller than TEMPC, the intermediate value TEMPO is defined as the final code, just as it is. In contrast, when the coding register value C is equal to or larger than TEMPC, a value which is obtained by subtracting 0x8000 from the coding register value C is defined as the final code.

After this process, up to the byte including the 15th bit counted from the highermost bit of the coding register is outputted. However, because it is prohibited according to JPEG2000 that the codes have a byte having a value of 0xFF at the end thereof, the last byte is discarded when the last byte is 0xFF. One or two bytes of code is then outputted from the coding register depending upon the number of times CT that a normalization has been carried out after the codes were outputted the last time.

Furthermore, according to JPEG2000, there is provided a function of additionally coding a specific bit sequence (1010) in every a certain number of cycles when performing a process of coding a binary symbol as a segmentation symbol in order to improve error resistance (refer to nonpatent reference 1). In the decoding processing, presence or absence of a transmission error is estimated by checking whether or not this specific bit sequence has been decoded correctly.
[Nonpatent reference 1] ITU-T Rec.T.800 |ISO/IEC 15444-1, Information technology-JPEG 2000 image coding system: Core coding system.http://www.jpeg.org/jpeg2000/index.html

A problem with conventional coding apparatuses is that when additional bits are added to an information source symbol which is a target to be coded, as mentioned above, the code length may increase and therefore the decoding side cannot determine how many additional bits have been coded from the received codes.

The present invention is made in order to solve the above-mentioned problem, and it is therefore an object of the present invention to provide a coding apparatus that can embed additional bits in an entropy-coded sequence without increasing the code length of the entropy-coded sequence, a decoding apparatus that decodes this code sequence, and a program that causes a computer to operate as these apparatuses.

### DISCLOSURE OF THE INVENTION

In accordance with the present invention, there is provided a coding apparatus that entropy-codes an information source symbol to generate a code sequence, the coding apparatus including: a number-of-additional-bits calculating means for calculating a number of bits which can be set, as additional bits, at an end of the code sequence on the basis of information about the end of the code sequence, the information being driven from code data which form the code sequence; and an additional bit coding means for setting the additional bits having the number of bits at the end of the code sequence.

As a result, the present invention provides an advantage of being able to embed the additional bits in the code sequence without increasing the code length of the code sequence.

### BRIEF DESCRIPTION OF THE FIGURES

FIG. 1 is a block diagram showing the structure of a coding apparatus in accordance with Embodiment 1 of the present invention;

FIG. 2 is a block diagram showing the structure of a decoding apparatus in accordance with Embodiment 1;

FIG. 3 is a diagram showing the structure of a coding register;

FIG. 4 is a diagram showing the structure of the coding register;

FIG. 5 is a diagram showing the structure of the coding register;

FIG. 6 is a diagram showing creation of cases in determination of the number of additional bits;

FIG. 7 is a diagram showing creation of cases in determination of the number of additional bits;

FIG. 8 is a diagram showing creation of cases in determination of the number of additional bits;

FIG. 9 is a flow chart showing a calculation process of calculating the number of additional bits which is carried out by the coding apparatus shown in FIG. 1;

FIG. 10 is a flow chart showing a calculation process of calculating the value of a coding side CT counter which is carried out by the decoding apparatus shown in FIG. 2;

FIG. 11 is a flow chart showing a calculation process of calculating the number of additional bits which is carried out by the decoding apparatus shown in FIG. 2;

FIG. 12 is a block diagram showing the structure of a code transforming apparatus in accordance with Embodiment 2 of the present invention;

FIG. 13 is a block diagram showing the structure of a decoding apparatus in accordance with Embodiment 2;

FIG. 14 is a diagram showing the structure of a coding register and a decoding register in accordance with Embodiment 2;

FIG. 15 is a flow chart showing a determination process of determining coder information in accordance with Embodiment 2;

FIG. 16 is a flow chart showing the determination process of determining the coder information in accordance with Embodiment 2;

FIG. 17 is a flow chart showing a calculation process of calculating the number of additional bits in accordance with Embodiment 2; and

FIG. 18 is a diagram showing an example of an arithmetic code sequence.

### PREFERRED EMBODIMENTS OF THE INVENTION

Hereafter, in order to explain this invention in greater detail, the preferred embodiments of the present invention will be described with reference to the accompanying drawings. Embodiment 1.

In this Embodiment 1, a coding process of making a binary symbol which is produced through coding of image data (simply referred to as a binary symbol from here on) be a target for arithmetic coding, coding additional bits which are additional information different from a binary symbol (simply referred to as additional bits from here on) immediately after the image data coding process is completed, and then performing a flush process on the coded additional bits and outputting a code, and a decoding process of extracting the additional bits embedded in this code will be explained. Embodiment 1 is based on that even the coding of the additional bits does not change the code length compared with a case in which flush for arithmetic coding (referred to as recommended flush from here on) described in nonpatent reference 1 is carried out (the coding of the additional bits is not carried out).

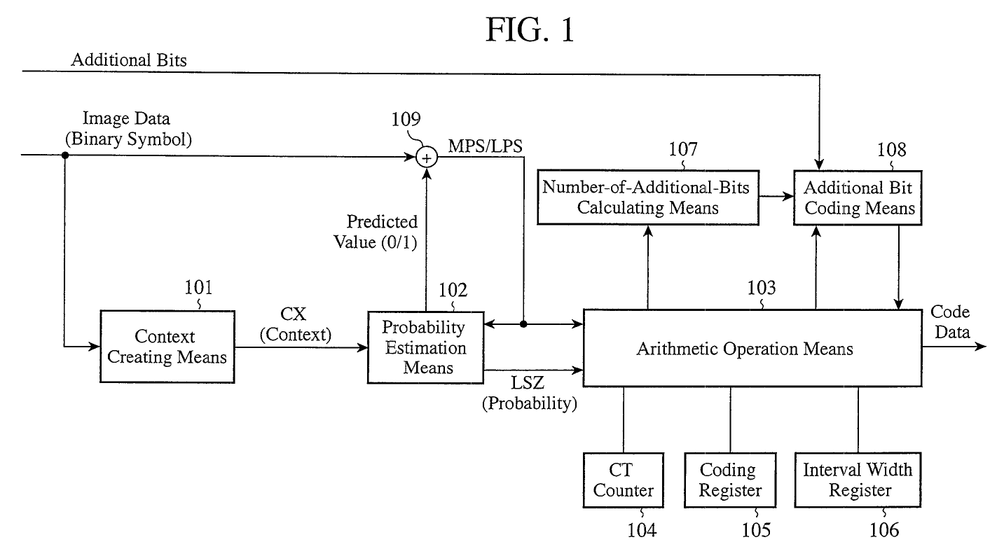

FIG. 1 is a block diagram showing the structure of a coding apparatus in accordance with Embodiment 1 of the present invention, and shows a case in which the present embodiment is applied to an image coding apparatus which carries out arithmetic coding of image data. In FIG. 1, a context creating means 101 determines a context CX which is provided for setting up a condition for estimation of the probability of occurrence of a binary symbol in image data which is a target to be coded. A probability estimation means 102 calculates both a predicted value of the binary symbol which is a target to be coded, and a parameter LSZ showing the probability of occurrence of the binary symbol from the context CX.

An arithmetic operation means 103 carries out an arithmetic operation on the basis of information showing whether or not the predicted value matches the binary symbol which is a target to be coded, i.e. whether the binary symbol which is a target to be coded is an MPS or an LPS (referred to as binary information (MPS/LPS) from here on), and the estimated probability (LSZ), and outputs code data. A CT counter 104 counts and stores the number of times that a normalization has been carried out after the code data has been outputted from the arithmetic operation means 103 immediately before.

A coding register 105 stores the lower bound of a valid interval corresponding to the coded binary symbol. Furthermore, when storing a code having a value of 0xFF, the coding register 105 inserts a bit value of 0 immediately after this code.

Furthermore, a carry of the coding register value which occurs during the coding arithmetic operation performed by the arithmetic operation means 103 is made to propagate up to a code byte outputted immediately before. In the coding register 105, when the immediately preceding code byte has a value of 0xFF and a carry occurs, the bit value of 0 inserted immediately after the value of 0xFF becomes a bit value of 1. As a result, because the carry is absorbed, the carry does not propagate up to the code byte preceding the bit value.

A numerical value defining the width of each of intervals into which the valid interval defined on a number line is divided according to the probability of occurrence of the binary symbol is stored in an interval width register 106. Furthermore, during the coding process, the interval width is updated by using A-LSZ (an upper interval width) or LSZ (a lower interval width). However, reference numeral A denotes the width of an immediately preceding valid interval during the coding process.

By using information which can be detected by a decoding side, including the value of the CT counter 104 and the value of the coding register 105 at the time when the coding of the binary symbol is completed, the code outputted immediately before the coding of the binary symbol is completed, and so on, a number-of-additional-bits calculating means 107 determines additional bits having a number of bits which can be coded within the limits that the code length does not differ from that in the case in which recommended flush is carried out.

An additional bit coding means 108 adds a value ΔC calculated for the coding of the additional bits to the coding register 105 so as to generate a code including the coded additional bits. An exclusive OR circuit 109 determines binary information (MPS/LPS) showing whether the binary symbol which is a target to be coded is an MPS or an LPS from the result of the exclusive OR of the binary symbol which is a target to be coded and the predicted value of the binary symbol inputted from the probability estimation means 102.

By loading a program for coding according to the purport of the present invention into a computer, and controlling the operation of the computer using the program, the context creating means 101, the probability estimation means 102, the arithmetic operation means 103, the number-of-additional-bits calculating means 107, and the additional bit coding means 108, which are mentioned above, can implement the coding apparatus shown in FIG. 1 as a concrete means in which software and hardware operate on the computer in corporation with each other.

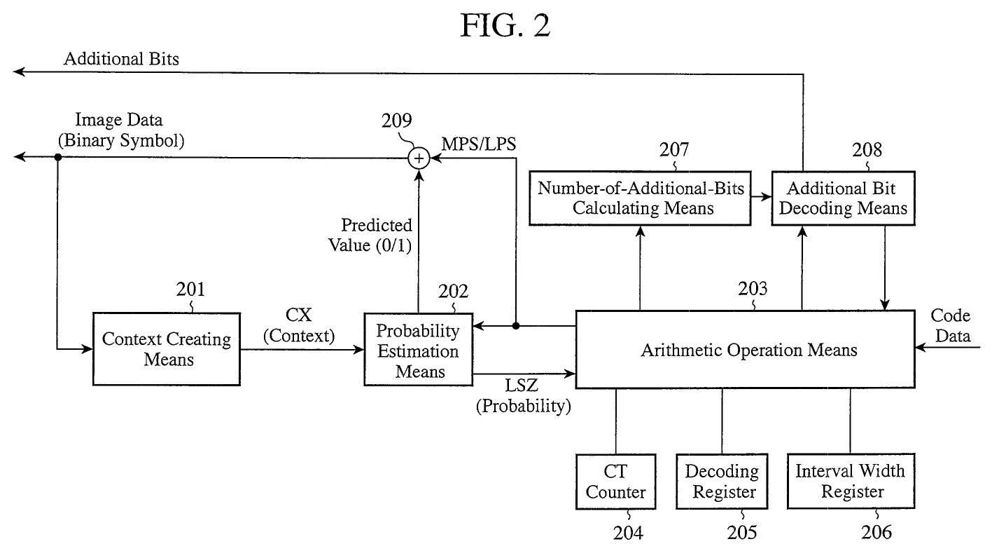

FIG. 2 is a block diagram showing the structure of a decoding apparatus in accordance with Embodiment 1, and shows a case in which the present embodiment is applied to an image decoding device which carries out arithmetic decoding of coded image data. In FIG. 2, a context creating means 201 determines a context CX which is provided for setting up a condition for estimation of the probability of occurrence of a binary symbol in coded data which is a target to be decoded. A probability estimation means 202 calculates both a predicted value of the binary symbol which is a target to be decoded, and a parameter LSZ showing the probability of occurrence of the binary symbol from the context CX.

An arithmetic operation means 203 determines whether or not the predicted value matches the binary symbol which is a target to be decoded, i.e. whether the binary symbol which is a target to be decoded is an MPS or an LPS from the code data and the estimated probability. A CT counter 204 counts and stores the number of times that a normalization has been carried out after the arithmetic operation means 203 has read the code data immediately before.

An offset from the lower bound of a valid interval corresponding to the decoded binary symbol to a code which is coordinates within the interval is stored in a decoding register 205.

A numerical value defining the width of each of intervals into which the valid interval on a number line is divided according to the probability of occurrence of the binary symbol is stored in an interval width register 206. A number-of-additional-bits calculating means 207 determines the number of additional bits included in the code data to be decoded. An additional bit decoding means 208 decodes the additional bits on the basis of information included in the end of the code sequence.

By loading a program for decoding according to the purport of the present invention into a computer, and controlling the operation of the computer using the program, the context creating means 201, the probability estimation means 202, the arithmetic operation means 203, the number-of-additional-bits calculating means 207, and the additional bit coding means 208, which are mentioned above, can implement the decoding apparatus shown in FIG. 2 as a concrete means in which software and hardware operate on the computer in corporation with each other.

Because the structure and fundamental functions of the computer can be recognized easily by those skilled in the art on the basis of the common general technical knowledge in the field of the present invention, and are not directly related to the essence of the present invention, the detailed description of the structure and fundamental functions of the computer will be omitted hereafter.

Next, the operation of the coding apparatus and that of the decoding apparatus will be explained.

The coding apparatus in accordance with Embodiment 1 shown in FIG. 1 encodes a binary symbol which is a target to be coded through the same process as that performed by an MQ coder described in nonpatent reference 1. The structures of the CT counter, the coding register, and the interval width register are also the same as those of nonpatent reference 1. At this time, the number-of-additional-bits calculating means 107 and the additional bit coding means 108 do not operate. More specifically, the image data which are a target to be coded are coded by the context creating means 101, the probability estimation means 102, the arithmetic operation means 103, the CT counter 104, the coding register 105, the interval width register 106, and the exclusive OR circuit 109, excluding the number-of-additional-bits calculating means 107 and the additional bit coding means 108, of the coding apparatus.

After the coding of a binary symbol which is a target to be coded is completed, the number-of-additional-bits calculating means 107 and the additional bit coding means 108 refer to the counted value of the CT counter 104 and the value of the coding register 105 at this time when the coding is completed, and the code outputted from the arithmetic operation means 103 immediately before the coding is completed, and determine the number of bits of the additional bits and then encodes the additional bits.

First, the processing procedure for coding the additional bits which is carried out by the number-of-additional-bits calculating means 107 and the additional bit coding means 108 will be explained.

### (1) A Process of Calculating the Number Lext of Bits of the Additional Bits to be Coded

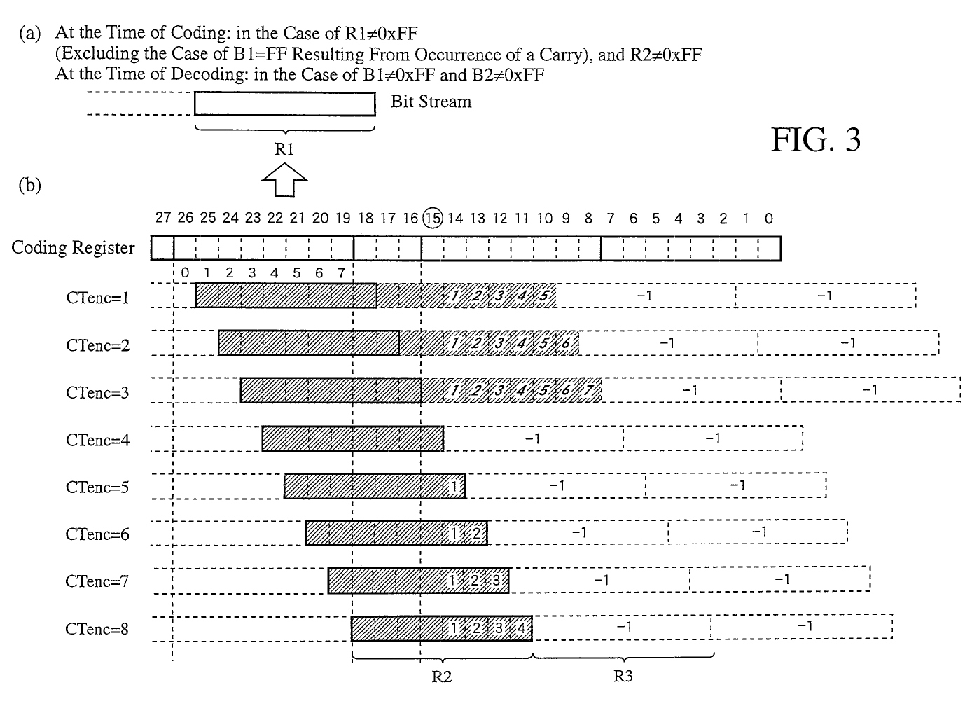

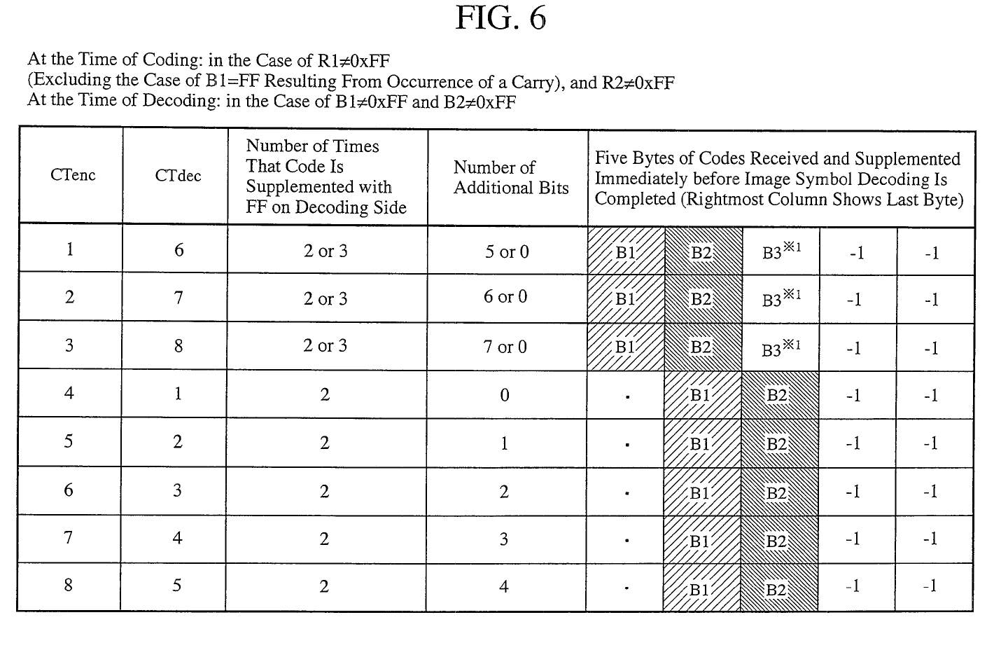

By using information which can be detected by the decoding side, including the counted value of the CT counter 104 and the value of the coding register 105 at the time when the coding of the binary symbol is completed, the code which the arithmetic operation means has outputted immediately before the coding is completed, and so on, the number-of-additional-bits calculating means 107 determines the number Lext of bits of the additional bits which can be coded within the limits that the code length does not differ from that in the case in which recommended flush is carried out. FIGS. 3 to 5 are diagrams showing the structure of the coding register, and creation of cases in the process of determining the number of additional bits shown in FIGS. 6 to 8 will be explained with reference to these diagrams.

In examples of FIGS. 3 to 5, a decimal point is set up between the 15th bit and the 16th bit of the coding register 105, and an upper portion to the left of the decimal point is an integer part and a lower portion to the right of the decimal point is a decimal fraction. Furthermore, the three bits from the 16th bit to the 18th bit of the integer part are a spacer bit interval Cs, the eight bits from the 19th bit to the 26th bit of the integer part are a byte output interval Cb, and the remaining single bit which is the 27th bit of the integer part is a carry determination interval Cc.

A byte enclosed by each solid line shown in FIGS. 3 to 5 indicates a code byte which is outputted as a code, and a byte in which italic numbers each enclosed by a dashed line are described shows a byte which is not outputted depending upon conditions. A byte shown by each −1 shown in FIGS. 3 to 5 and FIGS. 6 to 8 indicates a code which is supplemented with a byte which has a value of 0xFF because there is no code even if the byte is read by the decoding side. More specifically, in FIGS. 3 to 5, each byte which is enclosed by a dashed line and is marked with −1 is a byte which is not outputted and which is supplemented with FF by the decoding side.

In the normalizing process, in order to keep the significant digits to the right of the decimal point constant at the time of calculating the valid interval width A and the coding register value C during the coding, the decimal point positions of the valid interval width A and the coding register value C are shifted the same bits or digits to the right in such a way that the valid interval width A certainly falls within a range from 0.5 to 1.0. The CT counter 104 counts the number of shifts which have been performed on the coding register 105 and the interval width register 106, and an output of the code byte in the byte output interval Cb is carried out when the counted number of shifts becomes zero. The CT counter 104 has an initial value and a reset value which are both eight.

Furthermore, in FIGS. 3 to 5, the counted value of the CT counter 104 at the time when the coding of the binary symbol is completed is expressed as CTenc, 1 byte of code data outputted from the arithmetic operation means 103 immediately before the coding is completed is expressed as R1, the first code byte in the effective bits of the coding register 105 which are defined by the counted value of the CT counter 104 is expressed as R2, and the second code byte in the effective bits is expressed as R3. The final code bytes at the bit positions respectively corresponding to R1, R2, and R3 are respectively expressed as B1, B2, and B3.

For example, on the conditions of R1≠0xFF and R2≠0xFF, as shown in FIG. 3, when the value CTenc of the CT counter 104 is 1, the 18th to 25th bits of the coding register 105 are the code byte R2, the 10th to 17th bits of the coding register are the code byte R3, and the code byte outputted immediately before the coding is completed is R1. However, a case in which R1=0xFE and a carry has occurred in R1 from the coding register 105, i.e. a case in which R1=0xFE and the 26th bit of the coding register 105 is 1 in the example of FIG. 3 is excluded from the conditions shown in FIG. 3.

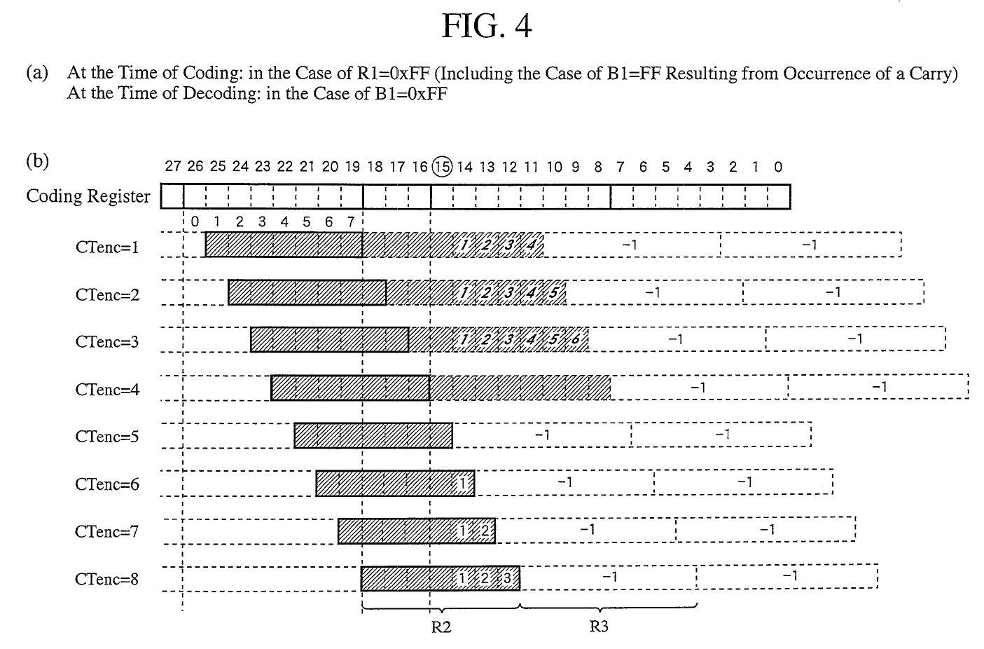

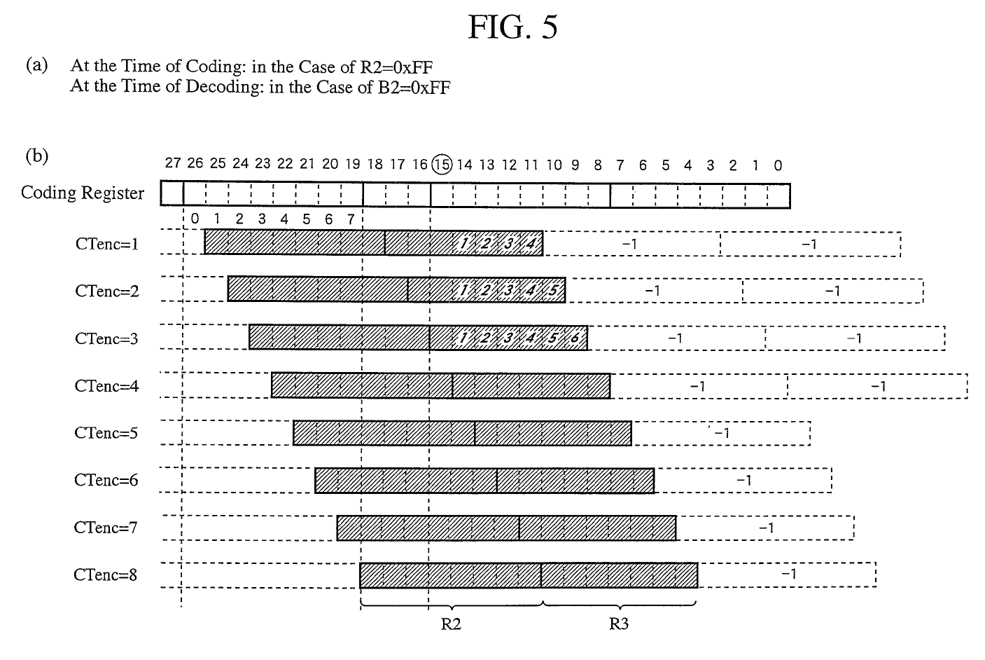

Furthermore, in a case in which B1=0xFF, as shown in FIG. 4, seven bits are outputted from the coding register 105 because one bit is inserted immediately after the code, as mentioned above. In the example of FIG. 4, when the value CTenc of the CT counter 104 is 1 on the above-mentioned conditions, the inserted one bit and the 19th to 25th bits are R2. Also on the conditions that B2=0xFF shown in FIG. 5, seven bits are outputted from the coding register 105 because one bit is inserted immediately after the code. In the example of FIG. 5, when the value CTenc of the CT counter 104 is one on the above-mentioned conditions, the 11th to 17th bits are R3.

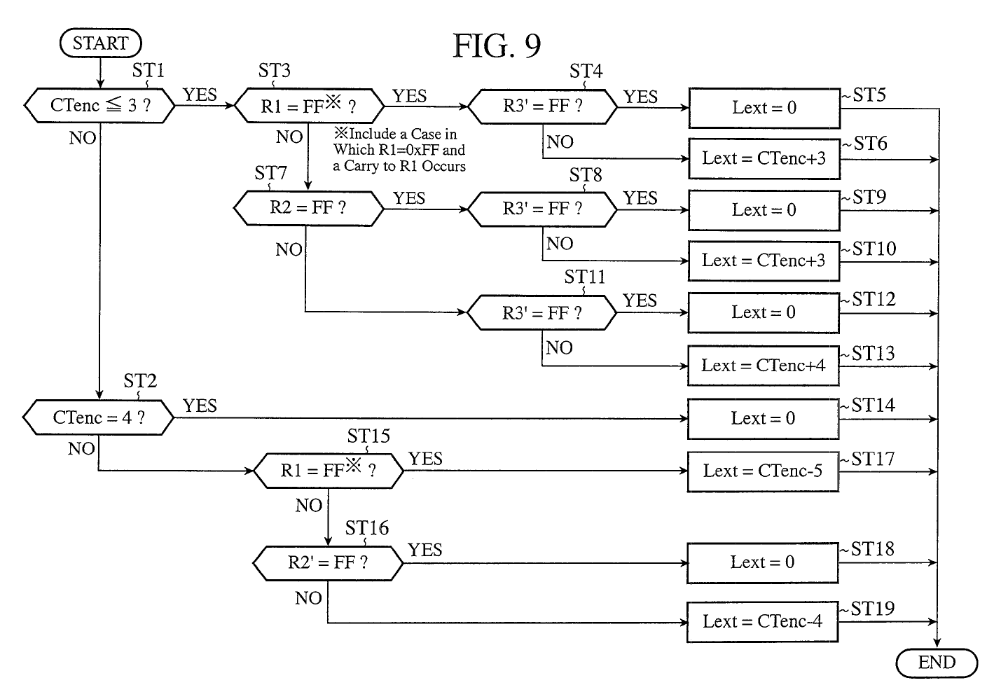

FIG. 9 is a flow chart showing the calculation process of calculating the number of additional bits which is carried out by the coding apparatus shown in FIG. 1, and the calculation procedure for calculating the number of additional bits will be explained with reference to this figure and FIGS. 6 to 8. R2′ and R3′ shown in FIG. 9 respectively denote bit sequences corresponding to R2 and R3 in a case in which recommended flush is carried out, and they are calculated as follows.

When the value of the coding register 105 at the time when the coding of the image data is completed is expressed as C and the value of the interval width register 106 at the time when the coding of the image data is completed is expressed as A, the coding apparatus calculates C′ by performing the next process.

C′=C OR 0xFFFF (OR indicates bitwise logical OR)

if (C′>=(C+A)) C′=C′−0x8000

With the variable C′, the bit sequence corresponding to R2 is made to become R2′ and the bit sequence corresponding to R3 is made to become R3′.

First, the number-of-additional-bits calculating means 107 determines whether or not the counted value CTenc of the CT counter 104 is three or less (step ST1). At this time, when the counted value CTenc of the CT counter 104 is not three or less, but is four or more, the number-of-additional-bits calculating means 17 advances to a process of step ST2.

In contrast, when the counted value CTenc of the CT counter 104 falls within the range from 1 to 3, the number-of-additional-bits calculating means 107 determines whether or not the code byte R1 has a value of 0xFF (step ST3). As mentioned above, the code byte R1 is assumed to have a value of 0xFF not only in a case in which the code byte R1 already outputted at the time when the coding of a binary symbol is completed has a value of 0xFF, but also in a case in which R1=0xFE and a carry has occurred in R1, i.e. in a case in which R1=0xFE and the value of the (27-CTenc) th bit of the coding register 105 is 1.

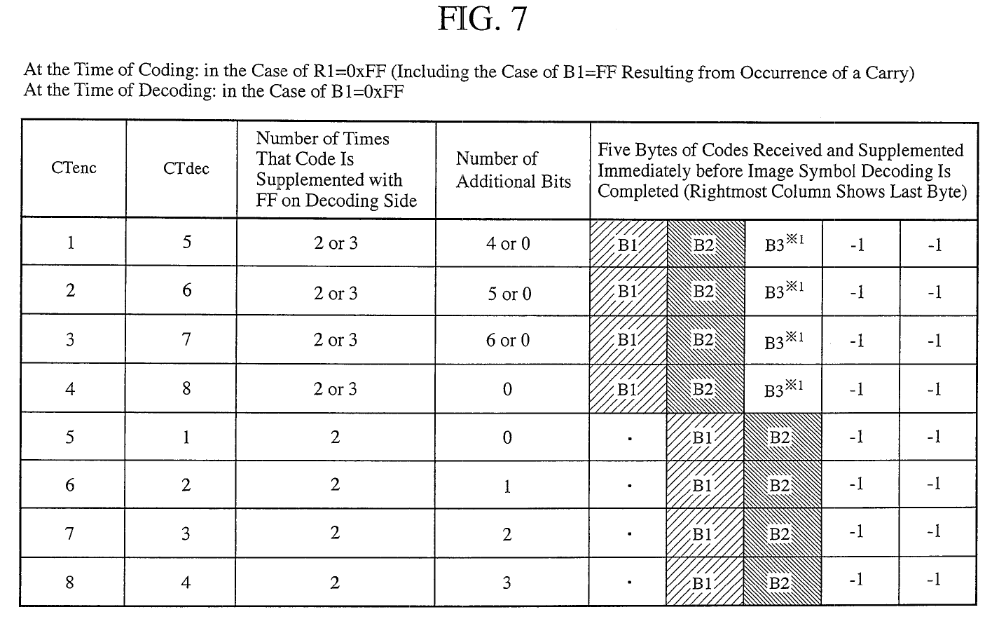

In the case in which R1 has a value of 0xFF, the number-of-additional-bits calculating means 107 determines whether or not R3′ has a value of 0xFF (step ST4). At this time, if R3′ has a value of 0xFF, the number-of-additional-bits calculating means 107 determines that the number Lext of bits of the additional bits is zero (step ST5), and ends the processing. In contrast, unless R3′ has a value of 0xFF, the number-of-additional-bits calculating means determines that the number Lext of bits of the additional bits is (CTenc+3) (step ST6), and ends the processing. The cases created in these steps ST5 and ST6 correspond to the 1-to-3 range of the counted value CTenc of the CT counter 109 shown in FIG. 7.

For example, when the counted value CTenc is 1 in the example of FIG. 7, the number Lext of bits of the additional bits is determined to be zero or (CTenc+3)=4 through the process of step ST5 or ST6. [symbol] shown in FIG. 7 shows a byte which is set to −1 depending on the conditions, and, in a case of −1, the number Lext of bits of the additional bits is determined to be zero. In FIG. 7, in a case in which the counted value CTenc ranges from 1 to 3, when B3′ has a value of 0xFF in step ST4, B3 is −1 and the number Lext of bits of the additional bits is determined to be zero.

When, in step ST3, the code byte R1 does not have a value of 0xFF, the number-of-additional-bits calculating means 107 determines whether or not the code byte R2 has a value of 0xFF (step ST7). At this time, if R2 has a value of 0xFF, the number-of-additional-bits calculating means advances to step ST8 and then determines whether or not R3′ has a value of 0xFF. If R3′ has a value of 0xFF, the number-of-additional-bits calculating means 107 determines that the number Lext of bits of the additional bits is zero (step ST9), and ends the processing. In contrast, unless R3′ has a value of 0xFF, the number-of-additional-bits calculating means determines that the number Lext of bits of the additional bits is (CTenc+3) (step ST10), and ends the processing.

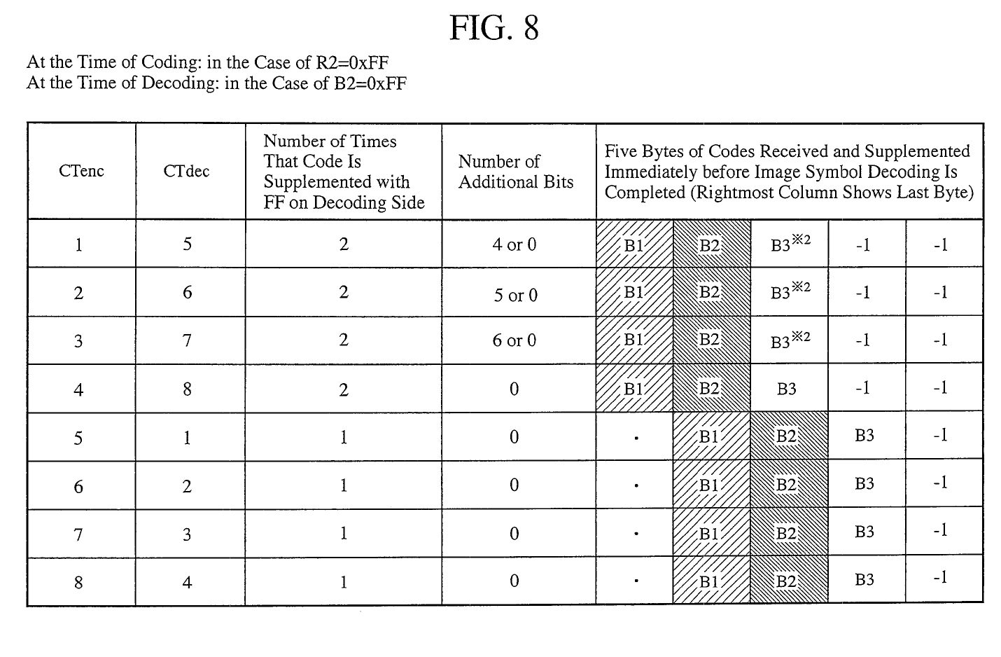

The cases created in these steps ST9 and ST10 correspond to the 1-to-3 range of the counted value CTenc of the CT counter 104 shown in FIG. 8. For example, in FIG. 8, when the counted value CTenc is 1, the number Lext of bits of the additional bits is determined to be zero or (CTenc+3)=4 through the process of step ST9 or ST10. [symbol] during FIG. 8 shows that the number Lext of bits of the additional bits is determined to be zero when B3 has a value of 0x7F.

When, in step ST7, R2 does not have a value of 0xFF, the number-of-additional-bits calculating means 107 determines whether or not R3′ has a value of 0xFF (step ST11). At this time, if R3′ has a value of 0xFF, the number-of-additional-bits calculating means 107 determines that the number Lext of bits of the additional bits is zero (step ST12), and ends the processing. In contrast, unless R3′ has a value of 0xFF, the number-of-additional-bits calculating means 107 determines that the number Lext of bits of the additional bits is (CTenc+4) (step ST13), and ends the processing.

The cases created in these steps ST12 and ST13 correspond to the 1-to-3 range of the counted value CTenc of the CT counter 104 shown in FIG. 6. For example, when the counted value CTenc is one in the example of FIG. 6, the number Lext of bits of the additional bits is determined to be zero or (CTenc+4)=5 through the process of step ST12 or ST13. [symbol] shown in FIG. 6 shows the same thing as that shown by [symbol] in the case of FIG. 7.

On the other hand, the number-of-additional-bits calculating means 107, in step ST2, determines whether or not the counted value CTenc is four. When the counted value CTenc is four, the number-of-additional-bits calculating means advances to step ST14, and then determines that the number Lext of bits of the additional bits is zero and ends the processing.

When the counted value CTenc is five or more, the number-of-additional-bits calculating means 107 determines whether or not R1 has a value of 0xFF (step ST15). In this case, when R1 has a value of 0xFF, the number-of-additional-bits calculating means 107 advances to step ST17, and determines that the number Lext of bits of the additional bits is (CTenc−5) and then ends the processing.

When, in step ST15, R1 does not have a value of 0xFF, the number-of-additional-bits calculating means 107 determines whether or not R2′ has a value of 0xFF (step ST16). In this case, if the code byte R2′ has a value of 0xFF, the number-of-additional-bits calculating means 107 determines that the number Lext of bits of the additional bits is zero (step ST18), and ends the processing. In contrast, unless the code byte R2′ has a value of 0xFF, the number-of-additional-bits calculating means determines that the number Lext of bits of the additional bits is (CTenc−4) (step ST19), and ends the processing.

The case created in this step ST14 corresponds to the range of 4 of the counted value CTenc of the CT counter 104 shown in FIGS. 6 to 8. Furthermore, the case created in step ST17 corresponds to the 5-to-8 range of the counted value CTenc of the CT counter 104 shown in FIG. 7. For example, when the counted value CTenc is 5 in the example of FIG. 7, the number Lext of bits of the additional bits is determined to be (CTenc−5)=0 through the process of step ST17.

The case created in step ST18 corresponds to the 5-to-8 range of the counted value CTenc of the CT counter 104 shown in FIG. 8. For example, when the counted value CTenc is 5 in the example of FIG. 8, the number Lext of bits of the additional bits is determined to be (CTenc−5)=0 through the process of step ST18. Furthermore, the case created in step ST19 corresponds to the 5-to-8 range of the counted value CTenc of the CT counter 104 shown in FIG. 6. For example, when the counted value CTenc is 5 in the example of FIG. 6, the number Lext of bits of the additional bits is determined to be (CTenc−4)=1 through the process of step ST19.

Thus, on the basis of the value of the coding register 105, the value of the interval width register 106, the number of times that a normalizing process has been carried out, and the code outputted from the coding register 105 immediately before the entropy coding is completed, which are information which can be detected by the decoding side, the number-of-additional-bits calculating means 107 determines the number of additional bits to be included in the code sequence, which is to be finally outputted as the code data, within the limits that the code length is not changed.

Each number of additional bits shown in FIGS. 6 to 8 is an example of the number of additional bits which can be coded. Furthermore, complicated conditions which are classified can be provided, and a larger number of additional bits can be coded within the limits that the code length does not exceed a predetermined condition. In contrast to this, a smaller number of additional bits than the numbers of additional bits shown in FIGS. 6 to 8 can be coded within the limits that the code length does not exceed a predetermined condition.

### (2) A Process of Reflecting the Additional Bits in the Coding Register Value

When the number Lext of bits of the additional bits is determined according to the above-mentioned procedure (1), the additional bit coding means 108 calculates a value ΔC corresponding to the additional bits by using the number Lext of bits of the additional bits according to the following equation (1). After that, the additional bit coding means 108 adds ΔC to the coding register C according to the following equation (2) so as to calculate a coding register value C″ in which the additional bits are reflected. Si, i.e. each of S1, S2, . . . , and S_{Lext} (Si=0 or 1) in the following equation (1) shows the value of each bit which constructs the additional bits.

$$\begin{matrix}[ Equation 1 ] & \\ Δ C = {\sum }_{i = 1}^{Lext} Si ≪ ( 15 - i ) & ( 1 ) \\ {C}^{″} = C + Δ C & ( 2 )\end{matrix}$$

The process according to the above-mentioned equation (1) is equivalent to addition of the values of the additional bits to the bits included in the code byte and each marked with a number in a case in which, for example, the counted value CTenc is one of the integers from 5 to 8 shown in FIG. 3. As a result, the additional bits are embedded in the end portion of the code byte while the code length is kept constant. Bits designated by italic characters shown in FIGS. 3 to 6 indicate that the number of additional bits is equal to zero depending upon the conditions (no additional bits are added). In the following explanation, the bytes corresponding to R2 and R3 which are stored in the coding register 105 to which ΔC has been added will be expressed as R2″ and R3″.

### (3) A Process of Outputting the Code

After adding ΔC to the coding register 105 according to the procedure (2) so as to acquire the coding register value C″, the additional bit coding means 108 notifies the arithmetic operation means 103 that the codes includes up to the byte including the 15th bit of the coding register 105 to which ΔC has been added. Accordingly, the arithmetic operation means 103 outputs this code as the code data.

For example, when the counted value CTenc of the CT counter 104 is 6 on the conditions for the creation of the cases: R1≠0xFF and R2≠0xFF which are shown in FIG. 3, the arithmetic operation means outputs the codes including up to R2″ (the value which is acquired by adding the additional bits to the 2 bits of the end portion of R2 through the addition of ΔC). Furthermore, when the counted value CTenc is one on the conditions for the creation of the cases: R1≢0xFF and R2≠0xFF which are shown in FIG. 3, the arithmetic operation means also refers to R3′ through the process of step ST11 shown in FIG. 9, and, when R3′≠0xFF, sets the number of additional bits to zero, whereas when R3′≠0xFF, the arithmetic operation means outputs up to R3″ as the code.

On the other hand, when the number Lext of bits of the additional bits is determined to be zero through the procedure (1), the additional bit coding means 108 notifies the arithmetic operation means 103 that the number Lext of bits of the additional bits is zero. Accordingly, the arithmetic operation means 103 performs the recommended flush process on the value of the coding register 105. In the recommended flush, the arithmetic operation means typically outputs 2 bytes of R2’ and R3′, as the code, from the coding register 105, though, when R3′ has a value of 0xFF, the arithmetic operation means does not output R3′.

Hereafter, the processes (1) to (3) of embedding the additional bits will be explained by providing a concrete example.

It is assumed that the value C of the coding register 105 is 0x1440468, the counted value CTenc of the CT counter 104 is 2, and the byte R1 has a value of 0xF5 at the time when the coding of a binary symbol is completed. In this case, because R2=0xA2 and R3=0x02, the number Lext of bits of the additional bits is determined to be six according to the flow chart shown in FIG. 9.

Assuming that the 6-bit additional bits have a value of {110100}, ΔC=0x6800 is acquired according the above-mentioned equation (1), and the coding register value C″ in which the additional bits are reflected becomes equal to C+ΔC=0x1446C68 according the above-mentioned equation (2). At this time, the bytes R2″ and R3″ respectively corresponding to the above-mentioned bytes R2 and R3 respectively become R2″=0xA2 and R3″=0x36. As a result, the last three bytes of the code sequence of the code data which are finally outputted from the arithmetic operation means 103 are F5, A2, and 36.

In the above-mentioned explanation, the example in which ΔC is added to calculate C″ through the procedure (2), and the codes are outputted through the procedure (3) is shown. In the procedure (2), instead of using the above-mentioned processing procedure, each following variable can be set to a fixed value at the time when the coding of the binary symbol is completed (no learning is carried out), and only the additional bits whose number of bits is determined in the procedure (1) can be coded by using a process of a typical QM coder. By thus outputting the codes through the procedure (3), the completely-same coded result can be acquired.

The value A of the interval width register 106=0x8000

The interval width of the more probable symbol (MPS)=0x4000

The interval width of the less probable symbol (LPS)=0x4000

The more probable symbol MPS=1, and the less probable symbol LPS=0

Next, processing carried out by the decoding side will be explained.

The decoding apparatus in accordance with Embodiment 1 shown in FIG. 2 decodes code data about an image by performing the same process as that performed by the MQ coder described in nonpatent reference 1. The structures of the CT counter, the coding register, and the interval width register are also the same as those disclosed in nonpatent reference 1. At this time, the number-of-additional-bits calculating means 207 and the additional bit decoding means 208 do not operate. More specifically, the context creating means 201, the probability estimation means 202, the arithmetic operation means 203, the CT counter 204, the decoding register 205, the interval width register 206, and the exclusive OR circuit 209, excluding the number-of-additional-bits calculating means 207 and the additional bit decoding means 208, of the decoding apparatus decode the code data about the image.

After a final binary symbol which is obtained by decoding a binary symbol is decoded, the number-of-additional-bits calculating means 207 and the additional bit decoding means 208 refer to the counted value of the CT counter 204 and the value of the decoding register 205 at this time, and the code read by the arithmetic operation means 203 immediately before the decoding, and determines the number of bits of the additional bits and then decodes the additional bits.

Hereafter, the processing procedure for decoding the additional bits which is carried out by the number-of-additional-bits calculating means 207 and the additional bit decoding means 208 will be explained.

### (1a) A Process of Calculating the Counted Value CTenc of the Coding Side CT Counter

The number-of-additional-bits calculating means 207 calculates the counted value CTenc of the CT counter 104 at the time when the coding of the binary symbol is completed by the coding side from the counted value CTdec of the CT counter 204 at the time when the decoding of the binary symbol is completed. As shown in FIGS. 6 to 8, the counted value of the CT counter 104 on the coding side is not the same as that of the CT counter 204 on the decoding side, and the difference between them also varies due to occurrence of a byte having a value of 0xFF.

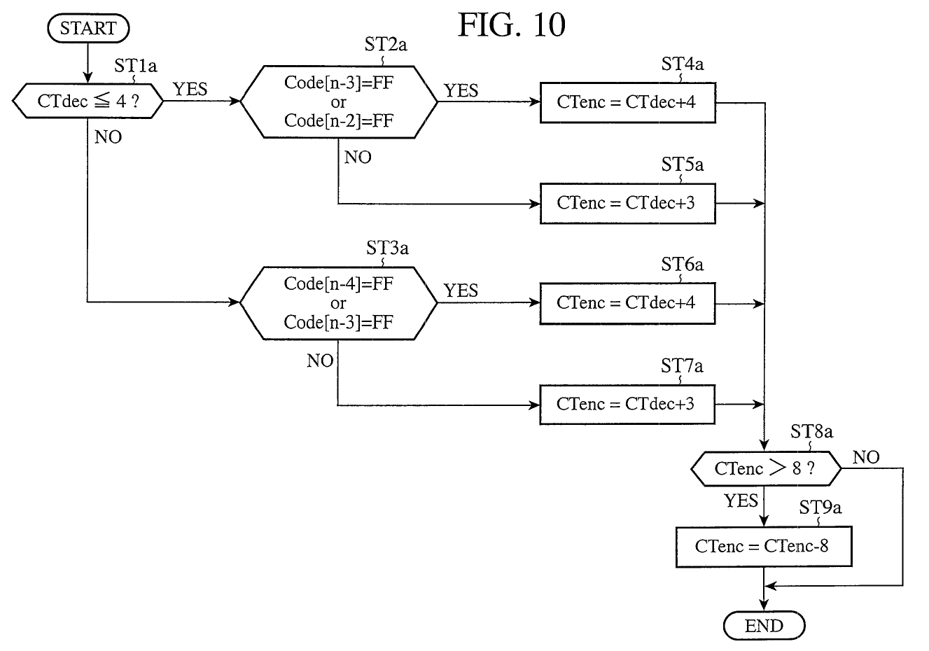

FIG. 10 is a flowchart showing the process of calculating the counted value CTenc of the coding side CT counter which is carried out by the image decoding device shown in FIG. 2, and the procedure for calculating the counted value CTenc of the CT counter 104 will be explained with reference to this figure. Code[i] shown in FIG. 10 denotes the code which has been read by the decoding side by the time the decoding of the binary symbol is completed. In this case, the last byte is Code[n], and the bytes preceding the last byte are Code[n-1], Code[n-2], Code[n-3], . . . which are listed in the order of being close to the last byte.

First, the number-of-additional-bits calculating means 207 determines whether or not the counted value CTdec of the CT counter 204 is four or less (step ST1a). At this time, when the counted value CTdec of the CT counter 204 is four or less, the number-of-additional-bits calculating means 207 advances to a process of step ST2a. In step ST2a, the number-of-additional-bits calculating means 207 determines whether or not either one of the code Code[n-3] (corresponding to B2) and the code Code[n-2] (corresponding to B3) which are read by the decoding side has a value of 0xFF.

In this case, when either one of the code Code[n-3] and the code Code[n-2] has a value of 0xFF, the number-of-additional-bits calculating means 207 determines that the value CTenc of the CT counter 104 on the coding side is (CTdec+4) (step ST4a), and advances to a process of step ST8a. In contrast, when neither the code Code[n-3] nor the code Code[n-2] has a value of 0xFF, the number-of-additional-bits calculating means determines that the value CTenc of the CT counter 104 on the coding side is (CTdec+3) (step ST5a), and advances to the process of step ST8a.

In contrast, when, in step ST1a, the counted value CTdec of the CT counter 204 is not four or less, but is five or more, the number-of-additional-bits calculating means 207 advances to a process of step ST3a. In step ST3a, the number-of-additional-bits calculating means 207 determines whether or not either one of the code Code[n-4] (corresponding to B1) and the code Code[n-3] which are read by the decoding side has a value of 0xFF.

When, in step ST3a, either one of the code Code[n-4] and the code Code[n-3] has a value of 0xFF, the number-of-additional-bits calculating means 207 determines that the value CTenc of the CT counter 104 on the coding side is (CTdec+4) (step ST6a), and advances to the process of step ST8a. In contrast, when neither the byte Code[n-4] nor the Code[n-3] has a value of 0xFF, the number-of-additional-bits calculating means determines that the value CTenc of the CT counter 104 on the coding side is (CTdec+3) (step ST7a), and advances to the process of step ST8a.

In step ST8a, the number-of-additional-bits calculating means 207 determines whether or not the counted value CTenc determined in either of the processes of steps ST4a to ST7a exceeds eight. At this time, when the counted value CTenc does not exceed 8, the number-of-additional-bits calculating means 207 ends the processing, whereas when the counted value CTenc exceeds eight, the number-of-additional-bits calculating means makes a transition to a process of step ST9a. In step ST9a, the number-of-additional-bits calculating means 207 sets a value which the number-of-additional-bits calculating means has acquired by subtracting eight from the counted value CTenc to the counted value CTenc.

Thus, the number-of-additional-bits calculating means 207 can calculate the counted value CTenc of the CT counter 104 on the coding side at the time when the coding of the binary symbol is completed on the basis of the values of the codes which have been read by the decoding side by the time the decoding of the binary symbol is completed.

### (2a) A Process of Calculating the Number Lext of Bits of the Additional Bits to be Decoded

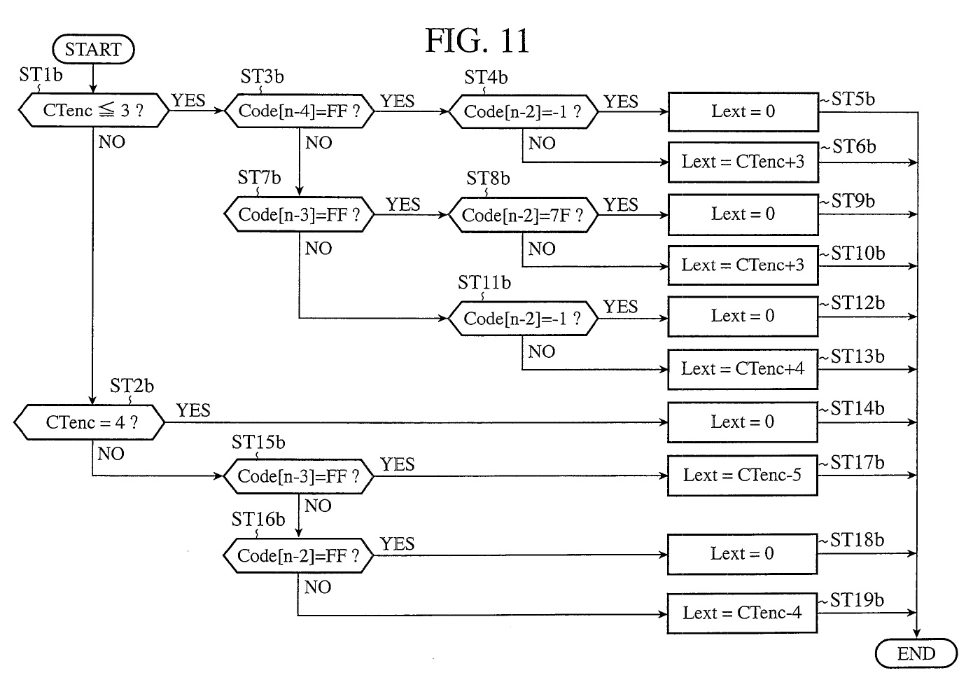

FIG. 11 is a flow chart showing the process of calculating the number Lext of bits of the additional bits to be decoded which is carried out by the image decoding device shown in FIG. 2, and the procedure for calculating the number of additional bits will be explained with reference to this figure and FIGS. 6 to 8.

First, the number-of-additional-bits calculating means 207 determines whether or not the value CTenc of the CT counter 104 on the coding side which is calculated through the procedure (1a) is three or less (step ST1b). At this time, when the counted value CTenc is not three or less, but is four or more, the number-of-additional-bits calculating means 207 advances to a process of step ST2b.

When CTenc ranges from 1 to 3, the number-of-additional-bits calculating means 207 determines whether or not the code Code[n-4] (corresponding to B1) has a value of 0xFF (step ST3b). In this case, when the code Code[n-4] has a value of 0xFF, the number-of-additional-bits calculating means 207 determines whether or not the code Code[n-2] (corresponding to B3) is −1 (step ST4b). As mentioned above, −1 indicates a code which is supplemented with a byte having a value of 0xFF because there is no code even if the byte is read by the decoding side.

When, in step ST4b, the code Code[n-2] is −1, the number-of-additional-bits calculating means 207 determines that the number Lext of bits of the additional bits is zero (step ST5b), and then ends the processing. In contrast, when the code Code[n-2] is not −1, the number-of-additional-bits calculating means determines that the number Lext of bits of the additional bits is (CTenc+3) (step ST6b), and then ends the processing. The cases created in these steps ST5b and ST6b correspond to the 1-to-3 range of the counted value CTenc of the CT counter 104 shown in FIG. 7.

For example, when the counted value CTenc is 1 (CTdec=5) in the example of FIG. 7, the number Lext of bits of the additional bits is determined to be zero or (CTenc+3)=4 through the process of step ST5b or ST6b. At this time, the five bytes of codes which have been received and supplemented with the value of 0xFF immediately before the decoding of the image data to a binary symbol is completed are as shown in FIG. 7, and the number of times that the five bytes of codes are supplemented with the value of 0xFF is either 2 times at which a byte in which −1 is set is supplemented with the value of 0xFF, or 3 times further including one time at which B3 is supplemented with the value of 0xFF. In the example of FIG. 7, when the counted value CTenc ranges from 1 to 3 (CTdec ranges from 5 to 7), B3 is −1 and the number Lext of bits of the additional bits is determined to be zero if, in step ST4b, the code Code[n-2] is −1.

When, in step ST3b, the code Code[n-4] does not have a value of 0xFF, the number-of-additional-bits calculating means 207 determines whether or not the code Code[n-3] (corresponding to B2) has a value of 0xFF (step ST7b). In this case, when the code Code[n-3] has a value of 0xFF, the number-of-additional-bits calculating means advances to step ST8b and determines whether or not the code Code[n-2] has a value of 0x7F. When the code Code[n-2] has a value of 0x7F, the number-of-additional-bits calculating means 207 determines that the number Lext of bits of the additional bits is zero (step ST9b), and then ends the processing. In contrast, when the code Code[n-2] does not have a value of 0x7F, the number-of-additional-bits calculating means determines that the number Lext of bits of the additional bits is (CTenc+3) (step ST10b), and then ends the processing.

The cases created in these steps ST9b and ST10b correspond to the 1-to-3 range of the counted value CTenc of the CT counter 104 shown in FIG. 8. For example, when the counted value CTenc is 1 in the example of FIG. 8, the number Lext of bits of the additional bits is determined to be zero or (CTenc+3)=4 through the process of step ST9b or ST10b. At this time, the five bytes of codes which have been received and supplemented with the value of 0xFF immediately before the decoding of the image data to a binary symbol is completed are as shown in FIG. 8, and the number of times that the five bytes of codes are supplemented with the value of 0xFF is 2 times at which a byte in which −1 is set is supplemented with the value of 0xFF.

When, in step ST7b, the code Code[n-3] does not have a value of 0xFF, the number-of-additional-bits calculating means 207 determines whether or not the code Code[n-2] is −1 (step ST11b). In this case, when the code Code[n-2] is −1, the number-of-additional-bits calculating means 207 determines that the number Lext of bits of the additional bits is zero (step ST12b), and then ends the processing. In contrast, when the code Code[n-2] is not −1, the number-of-additional-bits calculating means determines that the number Lext of bits of the additional bits is (CTenc+4) (step ST13b), and then ends the processing.

The cases created in these steps ST12b and ST13b correspond to the 1-to-3 range of the counted value CTenc shown in FIG. 6. For example, when the counted value CTenc is one in the example of FIG. 6, the number Lext of bits of the additional bits is determined to be zero or (CTenc+4)=5 through the process of step ST12b or ST13b. At this time, the five bytes of codes which have been received and supplemented with the value of 0xFF immediately before the decoding of the image data to a binary symbol is completed are as shown in FIG. 6, and the number of times that the five bytes of codes are supplemented with the value of 0xFF is either 2 times at which a byte in which −1 is set is supplemented with the value of 0xFF, or 3 times further including one time at which B3 is supplemented with the value of 0xFF.

On the other hand, the number-of-additional-bits calculating means 207, in step ST2b, determines whether or not the counted value CTenc is 4. When the counted value CTenc is 4, the number-of-additional-bits calculating means advances to step ST14b, and determines that the number Lext of bits of the additional bits is zero and then ends the processing.

When the counted value CTenc is five or more, the number-of-additional-bits calculating means 207 determines whether or not the code Code[n-3] has a value of 0xFF (step ST15b). In this case, when the code Code[n-3] has a value of 0xFF, the number-of-additional-bits calculating means 207 advances to step ST17b, and determines that the number Lext of bits of the additional bits is (CTenc−5) and then ends the processing.

In contrast, when, instep ST15b, the code Code[n-3] does not have a value of 0xFF, the number-of-additional-bits calculating means 207 determines whether or not the code Code[n-2] has a value of 0xFF (step ST16b). At this time, if the code Code[n-2] has a value of 0xFF, the number-of-additional-bits calculating means 207 determines that the number Lext of bits of the additional bits is zero (step ST18b), and then ends the processing. In contrast, unless the code Code[n-2] has a value of 0xFF, the number-of-additional-bits calculating means determines that the number Lext of bits of the additional bits is (CTenc−4) (step ST19b), and then ends the processing.

The case created in this step ST14b corresponds to the range of 4 of the counted value CTenc shown in FIGS. 6 to 8. Furthermore, the case created in step ST17b corresponds to the 5-to-8 range of the counted value CTenc shown in FIG. 7. For example, when the counted value CTenc is five in the example of FIG. 7, the number Lext of bits of the additional bits is determined to be (CTenc−5)=0 through the process of step ST17b.

The case created in step ST18b corresponds to the 5-to-8 range of the counted value CTenc shown in FIG. 8. For example, when the counted value CTenc is 5 in the example of FIG. 8, the number Lext of bits of the additional bits is determined to be (CTenc−5)=0 through the process of step ST18b. Furthermore, the case created in step ST19b corresponds to the 5-to-8 range of the counted value CTenc shown in FIG. 6. For example, when the counted value CTenc is five in the example of FIG. 6, the number Lext of bits of the additional bits is determined to be (CTenc−4)=1 through the process of step ST19b.

Thus, the number-of-additional-bits calculating means 207 determines the number of additional bits to be decoded which are included in the code sequence of the received code data on the basis of the value of the decoding register 205, the value of the interval width register 206, the number of times that a normalizing process has been carried out on the coding side, the number of times being calculated through the procedure (1a), and the code stored in the decoding register 205 immediately before the decoding of the image data to a binary symbol is completed.

### (3a) A Process of Decoding the Additional Bits

After the number Lext of bits of the additional bits to be decoded is determined according to the above-mentioned procedure (2a), in order to decode the additional bits having the determined number of bits, the additional bit decoding means 208 sets the variables regarding the arithmetic decoding by the arithmetic operation means 203 to have the same values as the interval width register 106, the interval width of the more probable symbol, and the interval width of the less probable symbol at the time when the coding apparatus which has generated the inputted code sequence coded the additional bits.

After the coding apparatus completes the coding of a binary symbol, if the following relations:

the value A of the interval width register 106=0x8000,

the interval width of the more probable symbol (MPS)=0x4000,

the interval width of the less probable symbol (LPS)=0x4000,

the more probable symbol MPS=1, and the less probable symbol LPS=0 are established,

the variables are set in such a way that the following relations:

the value A of the interval width register 206=0x8000,

the interval width of the more probable symbol (MPS)=0x4000,

the interval width of the less probable symbol (LPS)=0x4000,

the more probable symbol MPS=1, and the less probable symbol LPS=0 are established. While this decoding of the additional bits is carried out, no learning of the probability of occurrence is carried out.

With these settings, the arithmetic operation means 203 certainly carries out a normalization every time when the additional bit decoding means decodes one bit. The arithmetic operation means 203 repeats the decoding process using the MQ coder only a number of times corresponding to the number Lext of bits of the additional bits calculated through the procedure (2a), and transmits the additional bits to the additional bit decoding means 208. As a result, the additional bits are outputted from the additional bit decoding means 208.

Hereafter, the procedures (1a) to (3a) for decoding the additional bits will be explained by providing a concrete example.

Hereafter, it is assumed that the counted value CTdec of the CT counter 204 on the decoding side at the time when the decoding of the image data is completed is seven, and the five bytes of codes read into the decoding register 205 immediately before the decoding of the image data is completed are Code[n-4]=0xF5, Code[n-3]=0xA2, Code[n-2]=0x36, Code[n-1]=−1, and Code[n]=−1 (−1 means that the byte is supplemented with FF because there is no code).

Following the flow chart shown in FIG. 10, the value CTenc of the CT counter 104 reaches two at the time when the coding of the image data is completed. Furthermore, the number Lext of bits of the additional bits is determined to be six through the process according to the flow chart shown in FIG. 11. Next, the additional bit decoding means carries out the decoding, according to the MQ coder, of only the number of bits of the additional bits using the variable values set up through the procedure (3a) to reproduce the additional bits {110100}.

As mentioned above, the coding apparatus in accordance with this Embodiment 1 includes the number-of-additional-bits calculating means 107 for calculating the number of bits which can be set, as additional bits, at the end of a code sequence, which is acquired by entropy-coding an information symbol, on the basis of information about the end of the code sequence, the information being driven from code data which form the code sequence, and the additional bit coding means 108 for setting the additional bits having the number of bits at the end of the code sequence. Therefore, the coding apparatus in accordance with Embodiment 1 can embed the additional bits in the code sequence without increasing the code length of the code sequence. Furthermore, the coding apparatus in accordance with Embodiment can add attribution information, such as copyright information or parameters about an image input device, to the data, and, as a result, can improve the convenience of the image data.

Furthermore, when carrying out arithmetic coding of the additional bits, the coding apparatus in accordance with above-mentioned Embodiment 1 determines the number of additional bits from the value of the coding register 105, the value of the interval width register 106, the number of times that a normalization is carried out, and the code outputted from the coding register 105 immediately before the entropy coding is completed. Therefore, the coding apparatus can add the additional bits having the number of bits dependent upon the coding state or the status of the coder to the code sequence, and can therefore add information to the code sequence more efficiently.

In addition, in accordance with above-mentioned Embodiment 1, when performing arithmetic coding of the additional bits and arithmetic decoding of the additional bits, the valid interval A is set to a value larger than a predetermined value (e.g. one half of the entire interval), the value of the more probable symbol (MPS) is set to a fixed value of 0 or 1, and both the interval widths respectively corresponding to the more probable symbol MPS and the less probable symbol LPS are set to a fixed value which is one half of the entire interval. Therefore, one normalization certainly occurs during the coding of one symbol and during the decoding of one symbol. By doing in this way, the calculation of the code length of the addition symbol can be easily carried out.

Furthermore, in accordance with above-mentioned Embodiment 1, because the coding register generates, as codes, bytes including from the most significant byte determined from the number of times that a normalization has been carried out to a byte including a bit at a specific position, the flush process for the arithmetic coding can be simplified.

In addition, in accordance with above-mentioned Embodiment 1, because the additional bits are embedded in the code sequence in such a way that the code length does not change regardless of whether or not the additional bits are embedded in the code sequence, the same processes as those in the case in which no additional bits are embedded can be applied after the coding is carried out, and therefore the processes can be simplified.

Furthermore, in accordance with above-mentioned Embodiment 1, because the coding register to which a value generated by shifting the additional bit sequence by a specific number of bits is added generates, as codes, bytes including from the most significant byte determined from the number of times that a normalization has been carried out to a byte including a bit at a specific position, the process of carrying out the arithmetic coding of the plurality of additional bits on a bit-by-bit basis can be eliminated and therefore the coding process can be simplified.

### Embodiment 2.

In this Embodiment 2, a code transforming process of embedding additional bits which are additional information (simply referred to as additional bits from here on) different from a binary symbol which is produced through coding of image data (simply referred to as a binary symbol from here on) in a code sequence which is generated by carrying out arithmetic coding of the binary symbol by using an MQ coder described in nonpatent reference 1 (by using an arbitrary flush method), and a decoding process of extracting the additional bits embedded in this code sequence will be explained. Embodiment 2 is based on that even the embedding of the inputted additional bits into the code sequence does not change the code length of the code sequence (the number of bytes) compared with a case in which the inputted additional bits are not embedded in the code sequence.

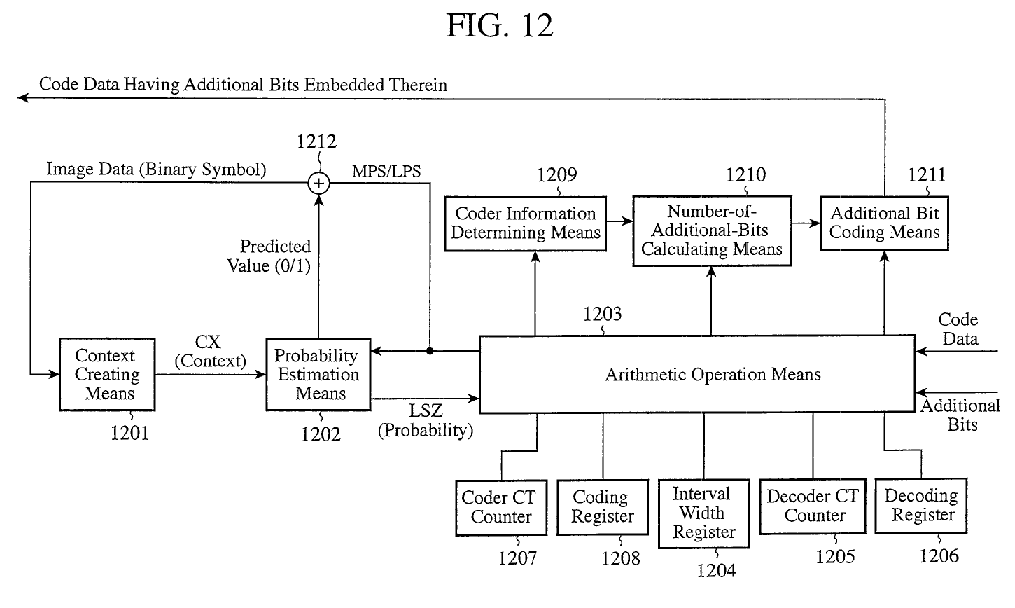

FIG. 12 is a block diagram showing the structure of a code transforming apparatus in accordance with Embodiment 2 of the present invention, and shows a case in which the present embodiment is applied to a code sequence which is acquired by carrying out arithmetic coding of image data. In FIG. 12, a context creating means 1201 determines a context CX which is provided for setting up a condition for estimation of the probability of occurrence of a binary symbol which is a target to be decoded. A probability estimation means 1202 calculates both a predicted value of the binary symbol which is a target to be decoded, and a parameter LSZ showing the probability of occurrence of the binary symbol from the context CX.

An arithmetic operation means 1203 determines whether or not the predicted value matches the binary symbol which is a target to be decoded, i.e. whether the binary symbol which is a target to be decoded is an MPS or an LPS from the code data and the estimated probability. A decoder CT counter 1205 counts and stores the number of times that a normalization has been carried out after the arithmetic operation means 203 has read the code data immediately before.

An offset from the lower bound of a valid interval corresponding to the decoded binary symbol to a code which is coordinates within the interval is stored in a decoding register 1206. A numerical value defining the width of each of intervals into which the valid interval on a number line is divided according to the probability of occurrence of the binary symbol is stored in an interval width register 1204.

The lower bound of a valid interval corresponding to the coded binary symbol at the time when the coding of the binary symbol is completed is stored in a coding register 1208. The number of times that a normalization has been carried out in the coding register 1208 is stored in a coder CT counter 1207.

A coder information determining means 1209 calculates the values of the coding register and the coder CT counter at the time when the coder which has generated the code data completes the coding from the values of the interval width register 1204, the decoder CT counter 1205, and the decoding register 1206 at the time when the decoding of the binary symbol is completed, and several bytes of codes which the coder information determining means has read immediately before the coding is completed.

A number-of-additional-bits calculating means 1210 determines the number of bits of additional bits which can be embedded. An additional bit coding means 1211 makes a correction to an end portion of the inputted code data in which the additional bits are embedded, and outputs a portion of the code data in which no additional bits are embedded, just as it is, without changing the portion.

By loading a program for code transformation according to the purport of the present invention into a computer, and controlling the operation of the computer using the program, the context creating means 1201, the probability estimation means 1202, the arithmetic operation means 1203, the coder information determining means 1209, the number-of-additional-bits calculating means 1210, and the additional bit coding means 1211, which are mentioned above, can implement the code transforming apparatus shown in FIG. 12 as a concrete means in which software and hardware operate on the computer in corporation with each other.

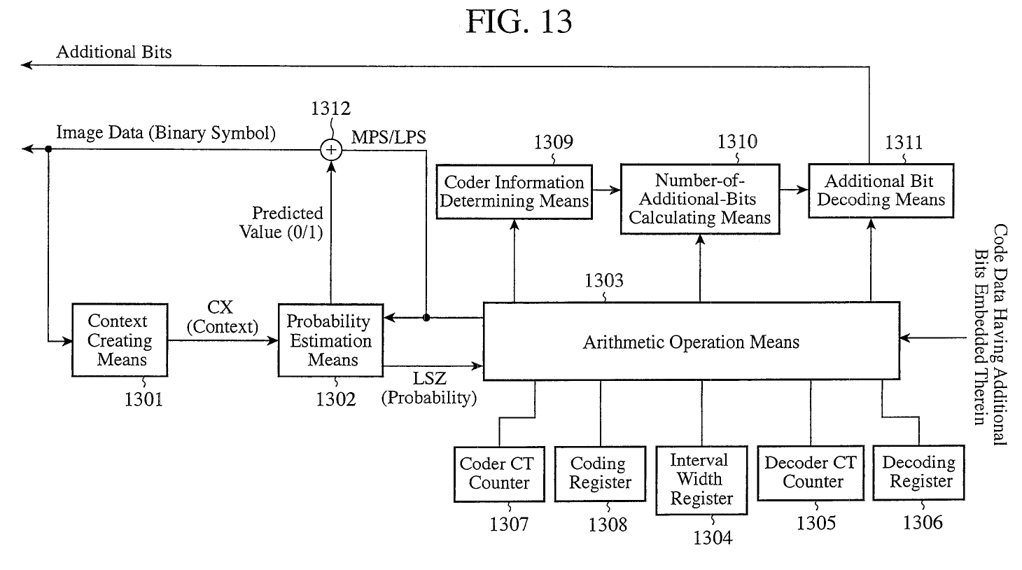

FIG. 13 is a block diagram showing the structure of a decoding apparatus in accordance with Embodiment 2, and shows a case in which the decoding apparatus in accordance with Embodiment 2 is applied to the code sequence generated by the code transforming apparatus in accordance with Embodiment 2. The decoding apparatus differs from the code transforming apparatus in accordance with Embodiment 2 in that the code data generated by the code transforming apparatus in accordance with Embodiment 2 are inputted thereto, the decoding apparatus outputs a decoded binary symbol and the additional bits which are embedded in the code data, and the decoding apparatus has an additional bit decoding means 1311 instead of the additional bit coding means 1211.

Because a coder CT counter 1307, a coding register 1308, an interval width register 1304, a decoder CT counter 1305, a decoding register 1306, a coder information determining means 1309, and a number-of-additional-bits calculating means 1310 are the same as those of the code transforming apparatus in accordance with Embodiment 2 shown in FIG. 12, and the explanation of the components will be omitted hereafter. After completing the decoding of a binary symbol, the additional bit decoding means 1311 carries out decoding of only the number of additional bits embedded in the inputted code sequence so as to extract the additional bits.

By loading a program for code transformation according to the purport of the present invention into a computer, and controlling the operation of the computer using the program, the context creating means 1301, the probability estimation means 1302, the arithmetic operation means 1303, the coder information determining means 1309, the number-of-additional-bits calculating means 1310, and the additional bit coding means 1311, which are mentioned above, can implement the code transforming apparatus shown in FIG. 13 as a concrete means in which software and hardware operate on the computer in corporation with each other.

Because the structure and fundamental functions of the computer can be recognized easily by those skilled in the art on the basis of the common general technical knowledge in the field of the present invention, and are not directly related to the essence of the present invention, the detailed description of the structure and fundamental functions of the computer will be omitted hereafter.

Next, the operation of the code transforming apparatus will be explained.

The code transforming apparatus in accordance with Embodiment 2 shown in FIG. 12 decodes code data about an image by performing the same process as that performed by the MQ coder described in nonpatent reference 1. The structures of the decoder CT counter, the decoding register, and the interval width register are also the same as those disclosed in nonpatent reference 1. At this time, the coder information determining means 1209, the number-of-additional-bits calculating means 1210, and the additional bit coding means 1211 do not operate. More specifically, the context creating means 1201, the probability estimation means 1202, the arithmetic operation means 1203, the coder CT counter 1207, the decoding register 1206, the interval width register 1204, and the exclusive OR circuit 1212, excluding the coder information determining means 1209, the number-of-additional-bits calculating means 1210, the additional bit coding means 1211, the coder CT counter 1207, and the coding register 1208, of the code transforming apparatus decode the binary symbol.

After the decoding of a binary symbol is completed, the coder information determining means 1209 and the number-of-additional-bits calculating means 1210 calculate the number of additional bits, and the additional bit coding means 1211 embeds the additional bits in the code data.

A variable Code[i] used in Embodiment 2 denotes a code which has been read by the decoding side by the time the decoding of the image data is completed, like in the case of above-mentioned Embodiment 1. In this case, the last byte is Code[n], and the bytes preceding the last byte are Code[n-1], Code[n-2], Code[n-3], . . . which are listed in the order of being close to the last byte. Although not shown in the block diagram, a memory for storing the latest five bytes of code data including from Code[n] to Code[n-4] is needed. In addition, the value Cenc of the coding register 1208 and the value CTenc of the coder CT counter 1207 are the same as the value Cenc of the coding register 105 and the value CTenc of the CT counter 104 which are shown in above-mentioned Embodiment 1, respectively.

(1c-1) A Process of Calculating Information About a Coder (the Coder CT Counter)

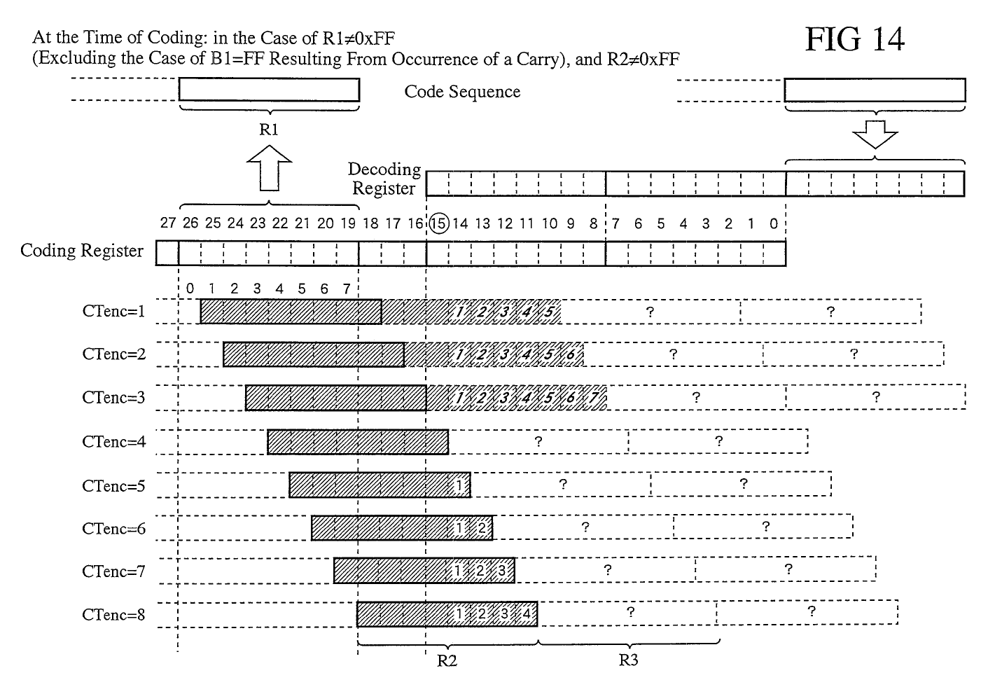

FIG. 14 is a diagram showing the structure of the coding register and the decoding register in accordance with Embodiment 2. In Embodiment 2, because any coding process is not performed on data other than the additional bits, the values of the coding register and the coder CT counter are not updated every time when a binary symbol is decoded. After the decoding of a binary symbol is completed, the values of the coding register and the CT counter at the time when a coder (i.e. a coder which is the same as that explained in Embodiment 1 and shown in FIG. 1, though not shown clearly) which generates the codes completes the coding of the binary symbol are reproduced by using a method which will be mentioned below, and the values are respectively set to the coding register 1208 and the coder CT counter 1207. One byte of code data outputted from the coding register of the coder (in the case of FIG. 1, the coding register 105) immediately before the coding of the binary symbol is completed is expressed as R1, the first code byte in the valid bits of the coding register which are defined by the value of the coder CT counter (in the case of FIG. 1, the CT counter 104) is expressed as R2, and the second code byte in the valid bits is expressed as R3. The final code data at the bit positions respectively corresponding to R1, R2, and R3 are respectively expressed as B1, B2, and B3. R2′ and R3′ respectively denote bit sequences corresponding to R2 and R3 in a case in which the following process required for recommended flush is carried out, and they are calculated as follows.

In a case in which the value of the coding register 1208 at the time when the coding of a binary symbol is completed is expressed as C and the value of the interval width register 1204 at the time when the coding of the binary symbol is completed is expressed as A, the apparatus calculates C′ by performing the next process.

C′=C OR 0xFFFF (OR indicates bitwise logical OR)

if (C′>=(C+A)) C′=C′−0x8000

With the variable C′, the bit sequence corresponding to R2 is made to become R2′ and the bit sequence corresponding to R3 is made to become R3′.

FIG. 14 shows the structure of the coding register and the decoding register in a case in which R1≠0xFF and R2′≠0xFF In addition, FIG. 14 shows at which positions in the coding register the bytes outputted as the codes are stored and at which position in the decoding register the inputted codes are stored in a case in which the value of the coder CT counter reaches each of the integers from 1 to 8 at the time when the coding of a binary symbol is completed.

For example, in a case in which the value CTenc of the coder CT counter is seven, the corresponding code data of the coding register at the time when the decoding of a binary symbol is completed are one byte diagonally shaded and two bytes succeeding the byte and each marked with “?”. In this case, it is assumed that the number of bytes to be read Num_Bytes which is a value indicating how many bytes of code data are included in the bytes from the most significant byte of the coding register to the least significant byte of the decoding register is three.

In this case, if recommended flush is carried out at the time of the coding, one byte diagonally shaded in FIG. 14 is the last byte, and each of the remaining 2 bytes has a value of 0xFF with which the byte is supplemented by the decoding side. However, if other flush is carried out, the bytes each marked with “?” in FIG. 14 may be outputted as the codes, or up to the succeeding byte may be outputted as the codes.

In addition, when each of these bytes has a value of 0xFF, the first bit of the further-succeeding byte is used as a control bit for carry. Therefore, only seven bits are read into the decoding register. Therefore, a process in consideration of occurrence of 0xFF into is needed, as will be mentioned below, at the time of the calculation of the value of the coder CT counter and the number of bytes to be read.

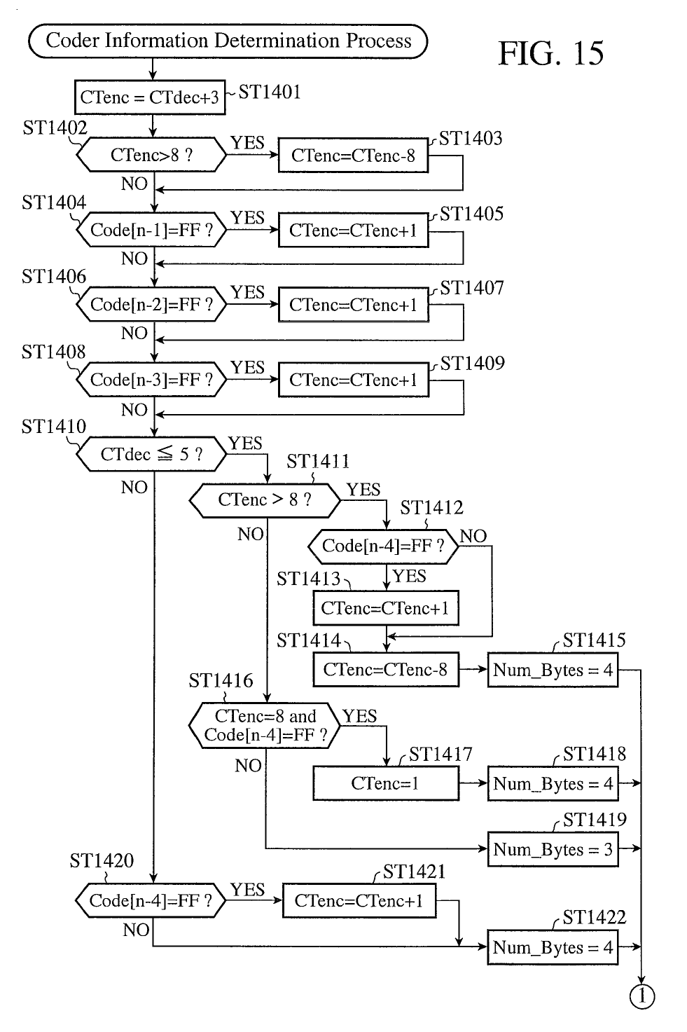

FIG. 15 is a flowchart showing the process of determining the coder information in accordance with Embodiment 2. The procedure for calculating the value CTenc of the coder CT counter 1207 and the number of bytes to be read Num_Bytes at the time at which the decoding of a binary symbol is completed will be explained with reference to the flow chart of this FIG. 15.

First, the coder information determining means 1209 calculates the value CTenc of the coder CT counter 1207 from the value CTdec of the decoder CT counter 1205. The coder information determining means 1209, in steps ST1401 to ST1403, calculates the value CTdec of the decoder CT counter 1207 in a case in which code data of 0xFF are not included in the bytes from the most significant byte of the coding register 1208 to the least significant byte of the decoding register 1206.

The coder information determining means 1209 then, in steps ST1404 to ST1409, adjusts the value of the coder CT counter 1207 by assuming a case in which 0xFF is included in the read code data. In this example, the coder information determining means checks whether or not 0xFF is included from the last byte to the last-but-two byte, and, when 0xFF is included from the last byte to the last-but-two byte, adds the number of 0xFFs which are included from the last byte to the last-but-two byte to the value CTenc.

The coder information determining means 1209, in step ST1410, determines whether or not the value of the decoder CT counter 1205 is five or less. While the number of bytes to be read Num_Bytes is certainly four when the value of the decoder CT counter is six or more, Num_Bytes is three or four when the value of the decoder CT counter is five or less.

When the value of the decoder CT counter 1205 is five or less, if determining that the value of the coder CT counter 1207 at the time of step ST1411 exceeds eight, the coder information determining means can determine that the number of bytes to be read is four. The coder information determining means 1209, in step ST1412, determines whether or not the last-but-four byte is 0xFF, and, if the last-but-four byte is 0xFF, adds one to the value CTenc of the coder CT counter 1207 in step ST1413. In addition, the coder information determining means 1209, in step ST1414, subtracts eight from the value CTenc of the coder CT counter 1207.

When the value CTenc of the coder CT counter 1207 at the time of step ST1411 is eight or less, the number of bytes to be read Num_Bytes is three or four. The coder information determining means 1209, in step ST1416, determines whether or not the following equations are simultaneously satisfied: the value of the coder CT counter CTenc=8 and Code[n-4]=0xFF. At this time, when the value CTenc=8 and Code[n-4]=0xFF (Yes), the value of the coder CT counter 1207 CTenc=1 and the number of bytes to be read Num_Bytes=4. Furthermore, only when the determination result in step ST1416 shows that the following equations are not simultaneously satisfied: the value CTenc=8 and Code[n-4]=0xFF, the coder information determining means can determine that the number of bytes to be read Num Bytes=3.

When the value CTenc of the decoder CT counter 1207 is six or more, the number of bytes to be read Num_Bytes is certainly four. Furthermore, when, step ST1420, determining that the last-but-four byte is 0xFF, the coder information determining means 1209 adds one to the value CTenc of the coder CT counter (step ST1421).

Through the above-mentioned process, the coder information determining means calculates the value CTenc of the coder CT counter 1207 and the number of bytes to be read Num_Bytes at the time at which the decoding of the binary symbol is completed (i.e. at the time at which the coding is completed).

(1c-2) A Process of Calculating the Information About the Coder (the Coding Register)

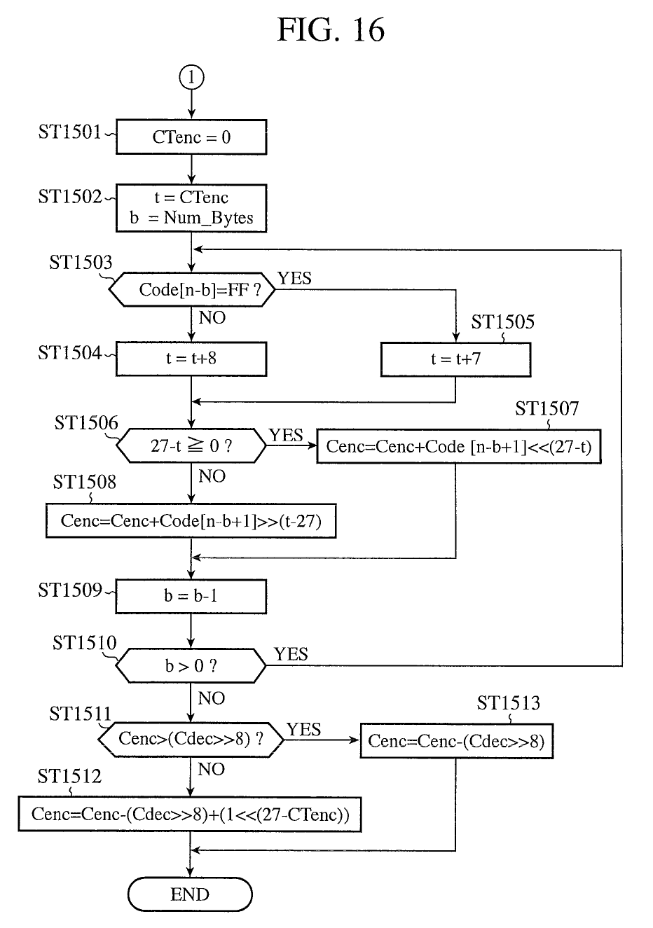

Next, the procedure for using the value CTenc of the coder CT counter 1207 acquired as shown in FIG. 15 and the number of bytes to be read Num_Bytes to calculate the value of the coding register 1208 will be explained with reference to a flow chart of FIG. 16 succeeding the flow chart of FIG. 15.

In the MQ coder, the value Cenc of the coding register 1208 at the time when the coding of a binary symbol is completed shows the lower bound of the last valid region. On the other hand, the decoding register 1206 shows the difference between the coordinates which are finally outputted as a code, and the lower bound of the valid region. In this process, the coder information determining means calculates the value of the coding register 1208 at the time when the coding of the binary symbol is completed by subtracting the value of the decoding register 1206 which is the difference between the coordinates which are finally outputted as a code and the lower bound of the valid region from the coordinates which are finally outputted as a code.

The coder information determining means 1209, in steps ST1501 to ST1510 shown in FIG. 16, reads the code data which are actually outputted, as codes, to the coding register 1208 (or which are supplemented with by the decoding side) to calculate the coordinates outputted as a code.

In a loop consisting of steps ST1503 to ST1510, the coder information determining means substitutes the code data having the number of bytes to be read Num_Bytes into the coding register 1208. Although not clearly shown in the block diagram, a variable t showing the number of bytes to be written in the coding register 1208, and a variable b showing at which bit position in the coding register 1208 each byte of the code data is to be written are used. Typically, 8 of bit positions are added to the variable b every time when one byte is written in the coding register, though when, in step ST1503, the byte to be written is determined to be 0xFF, 7 of bit positions are added to the variable b. Furthermore, it is assumed that when, in steps ST1507 and ST1508, Code[n-b+1]=−1 (supplemented with 0xFF), Code[n-b+1] is processed as Code[n-b+1]=0xFF.

The coder information determining means 1209 then, in steps ST1511 to ST1513, subtracts the value of the decoding register 1206 from the coordinates which are stored in the coding register 1208 and which are outputted as a code so as to calculate the lower bound of the valid region, i.e. the value of the coding register 1208 at the time when the coding of the binary symbol is completed.

The reason why the decoding register 1206 is shifted eight bits is because there is a 8-bit displacement between the coding register 1208 and the decoding register 1206 as shown in FIG. 14. Furthermore, the coder information determining means 1209, in step ST1511, determines whether or not a carry has occurred in the coding register 1208. When determining that a carry has occurred (when the result of the determination in step ST1511 shows No), the coder information determining means 1209, in step ST1512, sets the most significant bit of the coding register 1208 to 1.

In the above-mentioned method, the coder information determining means determines the information about the coder including the coding register 1208 and the coder CT counter 1207 from the available information at the time when the decoding of the binary symbol is completed. Unlike in this case, the code transforming apparatus in accordance with Embodiment 2 can also include an arithmetic coder which is an MQ coder, and can be constructed in such a way as to, every time when a binary symbol is decoded, carry out arithmetic coding of the binary symbol to acquire coder information at the time when the decoding of the binary symbol is completed. In this case, because the code transforming apparatus also carries out the arithmetic coding in parallel to the arithmetic decoding, the arithmetic load becomes high while the process of determining the information about the coder after the decoding is completed can be eliminated.

### (2c) A Process of Calculating the Number Lext of Bits of the Additional Bits

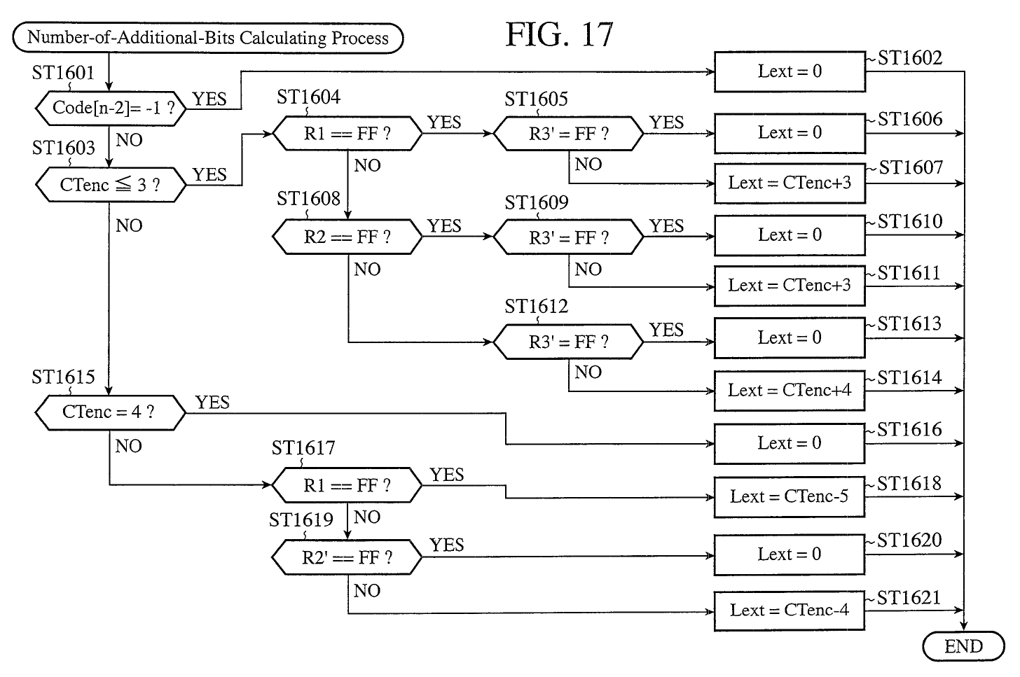

FIG. 17 is a flow chart showing the process of calculating the number of additional bits in accordance with Embodiment 2. The procedure for calculating the number Lext of bits of the additional bits to be embedded which does not change the inputted code sequence and the byte length will be explained with reference to this flow chart of FIG. 17. In Embodiment 2, it is assumed that the number of additional bits is calculated according to the same procedure as that shown in above-mentioned Embodiment 1, that is, the additional bits having the number of bits which can be embedded are embedded in a code sequence within the limits that the code length of a code sequence on which recommended flush is performed does not change. Furthermore, in this Embodiment 2, because arbitrary flush is assumed, it can also be considered that a code sequence longer than the code sequence on which recommended flush is performed is inputted. However, even in this case, additional bits longer than those shown in above-mentioned Embodiment 1 are not embedded.

In contrast with this, when the code sequence which is a target for embedding is shorter than the code sequence on which recommended flush is performed, the number Lext of bits of the additional bits to be embedded is set to zero. For this reason, the number-of-additional-bits calculating means 1210, in the first step ST1601 of the flow chart shown in FIG. 17, determines whether or not Code[n-2]=−1, i.e. whether or not the code which has been read previously and are preceding by three bytes is supplemented with 0xFF, and, if Yes, sets the number Lext of bits of the additional bits to be embedded to zero.

In the step of performing the process of calculating the number Lext of bits of the additional bits, the information about the coder including the coding register 1208 and the coder CT counter 1207 is determined. Therefore, because subsequent processes are the same as those in the case of above-mentioned Embodiment 1 shown in FIG. 11, the detailed explanation of the subsequent processes will be omitted hereafter. In this Embodiment 2, because there may be a case in which the code sequence has a code length different from that of a code sequence on which recommended flush is performed, in order to refer to the byte R1 which is outputted immediately before, the code transforming apparatus uses Num_Bytes calculated through the above-mentioned process (1c-1) so as to carry out R1=Code[n-Num_Bytes].

The above-mentioned number of additional bits is an example of the number of additional bits which can be coded. Furthermore, complicated conditions which are classified can be provided, and a larger number of additional bits can be coded within the limits that the code length does not exceed a predetermined condition. In contrast to this, a smaller number of additional bits than the above-mentioned number of additional bits can be coded within the limits that the code length does not exceed a predetermined condition.

### (3c) A Process of Reflecting the Additional Bits in the Coding Register Value

When the number Lext of bits of the additional bits is determined according to the above-mentioned procedure (2c), the additional bit coding means 1211 calculates a value ΔC corresponding to the additional bits according to the above-mentioned equation (1) shown in above-mentioned Embodiment 1. After that, the additional bit coding means 1211 adds ΔC to the coding register C according to the above-mentioned equation (2) so as to calculate a coding register value C″ in which the additional bits are reflected.

The above-mentioned procedure corresponds to a process of, after the decoding of a binary symbol is completed, coding the additional bits by setting each of the variables to a fixed value as follows.

The value A of the interval width register 1204=0x8000

The interval width of the more probable symbol (MPS)=0x4000

The interval width of the less probable symbol (LPS)=0x4000

The more probable symbol MPS=1, and the less probable symbol LPS=0

The variables are not necessarily set to the preset values as mentioned above, and can be alternatively to fixed values as follows. That is, if one renormalization occurs every time when the code transforming apparatus carries out coding (decoding) of one of the additional bits, an arbitrary method can be used.

The value A of the interval width register 1204=the interval width register value at the time when the decoding of a binary symbol is completed

The interval width of the more probable symbol (MPS)=(the interval width register value at the time when the decoding of a binary symbol is completed)/2

The interval width of the less probable symbol (LPS)=(the interval width register value at the time when the decoding of a binary symbol is completed)/2

The more probable symbol MPS=1, and the less probable symbol LPS=0

### (4c) A Process of Outputting Codes

The above-mentioned processes (1c) to (3c) are performed after the decoding of the image data to a binary symbol is completed, and, before the above-mentioned processes (1c) to (3c) are performed, the inputted code data are outputted without being changed, just as they are. Hereafter, the process of outputting codes after the decoding of the image data to a binary symbol is completed will be explained.

After adding ΔC to the coding register 1208 according to the procedure (3c) to acquire the coding register value C″, the additional bit coding means 1211 determines, as codes, up to a byte including the 15th bit of the coding register 1208 to which ΔC is added. After that, the additional bit coding means 1211 replaces the corresponding code data of the inputted code sequence with the determined code data. When the inputted code sequence further has a succeeding code, the code transforming apparatus performs the following process so as to make the code sequence outputted thereby have the same number of bytes as the inputted code sequence.

(4c-1) In a Case in Which it is One Byte Longer

When the next byte which is next to the byte to which ΔC is added is 0xFF in the value C of the coding register 1208, the embedding of the additional bits is not carried out and the inputted code sequence is outputted without being changed. This is because although the additional bits cannot be decoded correctly unless the next byte which is next to the byte to which ΔC is added is set to 0xFF, setting the last byte to 0xFF is prohibited in the MQ coder. When the next byte which is next to the byte to which ΔC is added has a value other than 0xFF, the codes are outputted with the next byte, i.e. the last byte of the codes being set to 0xFE.

(4c-2) In a Case in Which it is Two Bytes Longer

The first two bytes are set to 0xFF and 0x7F. After that, 0xFE is added and the number of bytes of the code sequence to be outputted is made to be the same as that of the inputted code sequence.

For example, in a case in which the counted value CTenc of the coder CT counter 1207 is six on the conditions shown in FIG. 14 (R1≠0xFF and R2≠0xFF), when the inputted code sequence is generated by carrying out recommended flush, up to R2″ (a value which is obtained by adding the additional bits to the 2 bits at the end of R2 with the addition of ΔC) is outputted as the codes. At this time, if recommended flush is carried out, R2″ is the last byte of the code sequence.

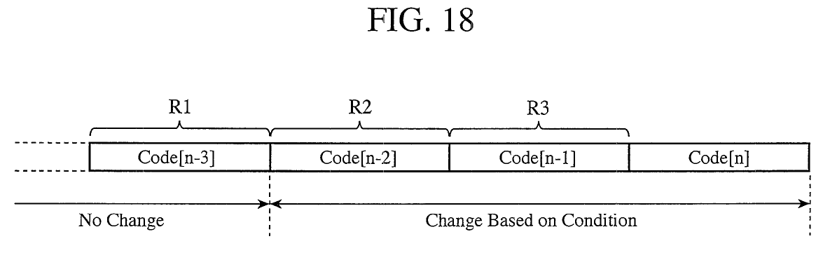

Hereafter, a case in which the inputted code sequence has a length which is two bytes longer than the number of bytes including up to R2 as shown in FIG. 18 will be considered. In this case, the additional bit coding means 1211 outputs up to the byte (Code[n-3]) corresponding to R1 without changing the inputted code data. The byte (Code[n-2]) corresponding to R2 is replaced by R2″. In addition, the remaining two bytes are replaced by 0xFF and 0x7F, and the code sequence having the same number of bytes as the inputted code sequence is outputted.

Next, the operation of the decoding side will be explained.

The decoding apparatus in accordance with Embodiment 2 shown in FIG. 13 decodes code data about an image first by performing the same process as that performed by the MQ coder described in nonpatent reference 1. The structures of the decoder CT counter 1305, the decoding register 1306, and the interval width register 1304 are also the same as those disclosed in nonpatent reference 1. At this time, the coder determining means 1309, the number-of-additional-bits calculating means 1310, and the additional bit decoding means 1311 do not operate. More specifically, the context creating means 1301, the probability estimation means 1302, the arithmetic operation means 1303, the coder CT counter 1305, the decoding register 1306, the interval width register 1304, and the exclusive OR circuit 1310, excluding the coder information determining means 1309, the number-of-additional-bits calculating means 1310, the additional bit decoding means 1311, the coder CT counter 1307, and the coding register 1308, of the decoding apparatus decode the code data about the image to generate a binary symbol.

After the additional bit decoding means 1311 has acquired a final binary symbol, the coder information determining means 1309 calculates the values of the coding register and the coder CT counter in the coder which has generated the code sequence. In addition, the number-of-additional-bits calculating means 1310 calculates the number of additional bits embedded in the code sequence, and the additional bit decoding means 1311 decodes the additional bits embedded in the code sequence. Because the processes of the coder information determining means 1309 and the number-of-additional-bits calculating means 1310 are the same as those of the coder information determining means 1209 and the number-of-additional-bits calculating means 1210 of the code transforming apparatus in accordance with Embodiment 2, the explanation of the processes will be omitted hereafter and the process of the additional bit decoding means 1311 will be explained hereafter.

After the number Lext of bits of the additional bits to be decoded is determined according to procedures which are the same as the above-mentioned procedures (1c) to (2a), in order to decode the additional bits having the number of bits, the additional bit decoding means 1311 sets the variables regarding the arithmetic decoding by the arithmetic operation means 1303 to have the same values as the interval width register 1204, the interval width of the more probable symbol, and the interval width of the less probable symbol, which were set at the time when the code transforming apparatus which has generated the inputted code sequence coded the additional bits.

After the code transforming apparatus completes the decoding of a binary symbol, if the following relations:

the value A of the interval width register 1204=0x8000,

the interval width of the more probable symbol (MPS)=0x4000,

the interval width of the less probable symbol (LPS)=0x4000,

the more probable symbol MPS=1, and the less probable symbol LPS=0 are established,

the variables are set in such a way that the following relations:

the value A of the interval width register 1304=0x8000,

the interval width of the more probable symbol (MPS)=0x4000,

the interval width of the less probable symbol (LPS)=0x4000,

the more probable symbol MPS=1, and the less probable symbol LPS=0 are established. While this decoding of the additional bits is carried out, no learning of the probability of occurrence is carried out.

With these settings, the arithmetic operation means 1303 certainly carries out a normalization every time when the additional bit decoding means decodes one bit. The arithmetic operation means 1303 repeats the decoding process using the MQ coder only a number of times corresponding to the number Lext of bits of the additional bits calculated according to the procedure (2c), and transmits the additional bits to the additional bit decoding means 1311. As a result, the additional bits are outputted from the additional bit decoding means 1311.

As mentioned above, the code transforming apparatus in accordance with the present Embodiment 2 is provided with the number-of-additional-bits calculating means 1210 for calculating the number of bits to be embedded, as additional bits, in the end of the code sequence on the basis of information about the end of the code sequence driven from the code data which construct the code sequence, and the additional bit coding means 1211 for transforming the code sequence in such a way that the additional bits having the number of bits are included in the code sequence. Therefore, the code transforming apparatus in accordance with this Embodiment 2 can embed the additional bits in the code sequence without increasing the code length of the code sequence. Furthermore, the code transforming apparatus in accordance with this Embodiment 2 can add attribution information, such as copyright information or parameters about an image input device, to the data, and, as a result, can improve the convenience of the image data.

### INDUSTRIAL APPLICABILITY

As mentioned above, because the coding apparatus in accordance with the present invention can embed additional bits in a code sequence without increasing the code length of the code sequence, the coding apparatus in accordance with the present invention can add attribution information, such as copyright information or parameters about an image input device, to the data, and therefore the coding apparatus in accordance with the present invention is suitable for use in an image coding apparatus that encodes image data.

1-20. (canceled)

21. A coding apparatus that entropy-codes an information source symbol to generate a code sequence, characterized in that said coding apparatus comprises:
a number-of-additional-bits calculating means for calculating a number of bits which can be set, as additional bits, at an end of said code sequence on a basis of information about the end of said code sequence, the information being driven from code data which form said code sequence; and
an additional bit coding means for setting the additional bits having said number of bits at the end of said code sequence.

22. The coding apparatus according to claim 21, characterized in that said coding apparatus comprises:
an arithmetic operation means for carrying out arithmetic coding of the information source symbol;
a coding register for storing coordinates showing a valid interval on a number line, the valid interval corresponding to the information source symbol coded by said arithmetic operation means;
an interval width register for storing a numerical value defining a width of each of intervals into which the valid interval on the number line is divided according to a probability of occurrence of the information source symbol; and
a CT counter for counting a number of times that a normalizing process of enlarging values of said interval width register and said coding register at a same magnification rate in such a way that the values become larger than a predetermined value when said interval width becomes smaller than a predetermined width has been carried out,
and characterized in that the number-of-additional-bits calculating means calculates the number of bits which can be set, as the additional bits, at the end of the code sequence on a basis of the value of said coding register, the value of said interval width register, and the number of times that a normalization has been carried out which is counted by said CT counter, these values being set at a time when said arithmetic operation means completes the arithmetic coding of the information source symbol, and a code outputted from said coding register immediately before the arithmetic coding is completed.

23. The coding apparatus according to claim 22, characterized in that the arithmetic operation means carries out binary arithmetic coding of the information source symbol, and, for said arithmetic operation means, the additional bit coding means sets the valid interval at a time when said arithmetic operation means completes the binary arithmetic coding of the information source symbol to have a value larger than a predetermined value, sets a more probable symbol to have a fixed value of 0 or 1, and sets both an interval width corresponding to said more probable symbol and an interval width corresponding to a less probable symbol to a fixed value which is one half of said entire interval, and encodes the additional bits.

24. The coding apparatus according to claim 22, characterized in that the additional bit coding means adds a value which the additional bit coding means has acquired by bit-shifting the additional bit sequence by a specific number of bits to the value of the coding register, and said coding register defines, as codes, bytes including from a most significant byte which is determined from the number of times that a normalization has been carried out which is counted during the coding process by the CT counter to a byte having a bit at a specific position.

25. The coding apparatus according to claim 23, characterized in that the number-of-additional-bits calculating means sets the number of additional bits in such a way that the additional bits have a code length which is equal to that of a code sequence in a case in which no additional bits are set.

26. The coding apparatus according to claim 24, characterized in that the number-of-additional-bits calculating means sets the number of additional bits in such a way that the additional bits have a code length which is equal to that of a code sequence in a case in which no additional bits are set.

27. A decoding apparatus that decodes a code sequence in which an information source symbol is entropy-coded, characterized in that said decoding apparatus comprises:
a number-of-additional-bits calculating means for calculating a number of bits which are set as additional bits from an end of said code sequence on a basis of information about the end of said code sequence, the information being driven from code data which form said code sequence; and
an additional bit decoding means for decoding the additional bits having said number of bits.

28. The decoding apparatus according to claim 27, characterized in that said decoding apparatus includes:
an arithmetic operation means for performing arithmetic decoding of the code sequence in which the information source symbol is arithmetic-coded;
a decoding register for storing an offset from coordinates showing a valid interval corresponding to the information source symbol decoded by said arithmetic operation means to a code which is coordinates within the interval;
an interval width register for storing a numerical value defining a width of each of intervals into which the valid interval on a number line is divided according to a probability of occurrence of the information source symbol; and
a CT counter for counting a number of times that a normalizing process of enlarging values of said interval width register and said decoding register at a same magnification rate in such a way that the values become larger than a predetermined value when said interval width becomes smaller than a predetermined width has been carried out,
and characterized in that the number-of-additional-bits calculating means calculates the number of bits of the additional bits which are set at the end of said code sequence on a basis of the number of times that a normalization has been carried out by a time when said arithmetic operation means completes the arithmetic decoding of the information source symbol, and a code inputted to said decoding register immediately before the arithmetic decoding is completed.

29. The decoding apparatus according to claim 28, characterized in that the arithmetic operation means performs the arithmetic decoding of the code sequence in which the information source symbol is binary-arithmetic-coded, and, for said arithmetic operation means, the additional bit decoding means sets the valid interval at a time when binary arithmetic coding of said information source symbol is completed to have a value larger than a predetermined value, sets a more probable symbol to have a fixed value of 0 or 1, and sets both an interval width corresponding to said more probable symbol and an interval width corresponding to a less probable symbol to a fixed value which is one half of said entire interval, and decodes the additional bits.

30. A program that causes a computer to operate as a coding apparatus that entropy-codes an information source symbol to generate a code sequence, wherein said program causes said computer to operate as a number-of-additional-bits calculating means for calculating a number of bits which can be set, as additional bits, at an end of said code sequence on a basis of information about the end of said code sequence, the information being driven from code data which form said code sequence, and an additional bit coding means for setting the additional bits having said number of bits at the end of said code sequence.

31. A program that causes a computer to operate as a decoding apparatus that decodes a code sequence in which an information source symbol is entropy-coded, wherein said program causes said computer to operate as a number-of-additional-bits calculating means for calculating a number of bits which are set as additional bits from an end of said code sequence on a basis of information about the end of said code sequence, the information being driven from code data which form said code sequence, and an additional bit decoding means for decoding the additional bits having said number of bits.

32. A code transforming apparatus that embeds additional bits in a code sequence in which an information source symbol is entropy-coded, characterized in that said code transforming apparatus comprises:
a number-of-additional-bits calculating means for calculating a number of bits which are to be embedded, as additional bits, at an end of said code sequence on a basis of information about the end of said code sequence, the information being driven from code data which form said code sequence; and
an additional bit coding means for transforming said code sequence in such a way that the additional bits having said number of bits are included in said code sequence.

33. The code transforming apparatus according to claim 32, characterized in that said code transforming apparatus comprises:
an arithmetic operation means for performing arithmetic decoding of the code sequence which is generated by performing arithmetic coding of the information source symbol;
a decoding register for storing an offset from coordinates showing a valid interval corresponding to the information source symbol decoded by said arithmetic operation means to a code which is coordinates within the interval;
an interval width register for storing a numerical value defining a width of each of intervals into which the valid interval on a number line is divided according to a probability of occurrence of the information source symbol;
a decoder CT counter for counting a number of times that a normalizing process of enlarging values of said interval width register and said decoding register at a same magnification rate in such a way that the values become larger than a predetermined value when said interval width becomes smaller than a predetermined width has been =Tied out; and
a coder information determining means for determining a state of a coder, which has generated said code sequence, at a time when the coder completes the generation of said code sequence,
and characterized in that the number-of-additional-bits calculating means calculates the number of additional bits which can be set at the end of said code sequence on a basis of the state of the coder, which has generated said code sequence, at the time when the coder completes the generation of said code sequence.

34. The code transforming apparatus according to claim 33, characterized in that said code transforming apparatus comprises:
a coding register for storing coordinates showing a valid interval on a number line, the valid interval corresponding to the information source symbol;
a coder CT counter for counting a number of times that a normalizing process of enlarging values of said interval width register and said coding register at a same magnification rate in such a way that the values become larger than a predetermined value when said interval width becomes smaller than a predetermined width has been carried out; and
a coder information determining means for calculating values of said coding register and said coder CT counter at the time when the coder which generates the code sequence completes the generation of the code sequence;
and characterized in that the arithmetic operation means carries out arithmetic coding of the additional bits having said number of additional bits to generate codes by using the values of said coding register and said coder CT counter which are calculated by said coder information determining means, and changes a corresponding byte included in said code sequence with the generated codes.

35. The code transforming apparatus according to claim 34, characterized in that when carrying out the coding of the additional bits, the arithmetic operation means sets the valid interval at a time when the arithmetic operation means completes binary arithmetic coding of the information source symbol to have a value larger than a predetermined value, sets a more probable symbol to have a fixed value of 0 or 1, and sets both an interval width corresponding to said more probable symbol and an interval width corresponding to a less probable symbol to a value which is one half of the setting of said invalid interval, and encodes the additional bits.

36. The code transforming apparatus according to claim 35, characterized in that the number-of-additional-bits calculating means sets the number of additional bits within limits that a byte length does not differ from that of the code sequence.

37. The code transforming apparatus according to claim 34, characterized in that when carrying out the coding of the additional bits, the arithmetic operation means adds a value which the arithmetic operation means has acquired by bit-shifting the additional bit sequence by a specific number of bits to the value of the coding register, and said coding register defines, as codes, bytes including from a most significant byte which is determined from the number of times that a normalization has been carried out which is counted during the coding process by the CT counter to a byte having a bit at a specific position.

38. The code transforming apparatus according to claim 37, characterized in that the number-of-additional-bits calculating means sets the number of additional bits within limits that a byte length does not differ from that of the code sequence.

39. The decoding apparatus according to claim 27, characterized in that said decoding apparatus comprises:
an arithmetic operation means for performing arithmetic decoding of the code sequence which is generated by performing arithmetic coding of the information source symbol;
a decoding register for storing an offset from coordinates showing a valid interval corresponding to the information source symbol decoded by said arithmetic operation means to a code which is coordinates within the interval;
an interval width register for storing a numerical value defining a width of each of intervals into which the valid interval on a number line is divided according to a probability of occurrence of the information source symbol;
a decoder CT counter for counting a number of times that a normalizing process of enlarging values of said interval width register and said decoding register at a same magnification rate in such a way that the values become larger than a predetermined value when said interval width becomes smaller than a predetermined width has been carried out; and
a coder information determining means for determining a state of a coder, which has generated said code sequence, at a time when the coder completes the generation of said code sequence,
and characterized in that the number-of-additional-bits calculating means calculates the number of bits of the additional bits which are set at the end of said code sequence on a basis of the state of the coder, which has generated said code sequence, at the time when the coder completes the generation of said code sequence.

40. The decoding apparatus according to claim 39, characterized in that when carrying out the decoding of the additional bits, the arithmetic operation means sets the valid interval at a time when the arithmetic operation means completes binary arithmetic decoding of the information source symbol to have a value larger than a predetermined value, sets a more probable symbol to have a fixed value of 0 or 1, and sets both an interval width corresponding to said more probable symbol and an interval width corresponding to a less probable symbol to a value which is one half of the setting of said valid interval, and decodes the additional bits.

41. A program that causes a computer to operate as a code transforming apparatus that embeds additional bits in a code sequence in which an information source symbol is entropy-coded, wherein said program causes said computer to operate as a number-of-additional-bits calculating means for calculating a number of bits which are to be embedded, as additional bits, at an end of said code sequence on a basis of information about the end of said code sequence, the information being driven from code data which form said code sequence, and an additional bit coding means for transforming said code sequence in such a way that the additional bits having said number of bits are included in said code sequence.
